(19) United States
(12) Patent Application Publication
(10) Pub. No.: US 2006/0041808 A1
(43) Pub. Date: Feb. 23, 2006

(54) Test-pattern generation system, test-pattern analysis system, test-pattern generation method, test-pattern analysis method, and computer product

(75) Inventor: Kazuyuki Yamamura, Kawasaki (JP)

Correspondence Address: STAAS & HALSEY LLP, SUITE 700, 1201 NEW YORK AVENUE, N.W., WASHINGTON, DC, 20005, US

(73) Assignee: Fujitsu Limited, Kawasaki (JP)

(21) Appl. No.: 11/023,504

(22) Filed: Dec. 29, 2004

(30) Foreign Application Priority Data
Aug. 20, 2004 (JP) 2004-241439

(51) Int. Cl. G01R 31/28; G06F 11/00

(52) U.S. Cl. 714/738

(57) ABSTRACT

An activation test sequence: 11XX0 with a test sequence ID: 8 is input to an ATPG to generate an activation test sequence: 11000. A propagation test sequence: 11XX1 with a test sequence ID: 8 is input to the ATPG to generate a propagation test sequence: 11011 with a test sequence ID: 9. A propagation test sequence: 11XX0 with a test sequence ID: 8 is input to the ATPG to generate a propagation test sequence: 11010 with a test sequence ID: 9. An activation test sequence: 11000 with a test sequence ID: 9, a propagation test sequence: 11011, and a propagation test sequence: 11010 are input to the ATPG to generate test patterns 11000XX, 11011XX, and 11011XH.

### CROSS-REFERENCE TO RELATED APPLICATIONS

This application is based upon and claims the benefit of priority from the prior Japanese Patent Application No. 2004-241439, filed on Aug. 20, 2004, the entire contents of which are incorporated herein by reference.

### BACKGROUND OF THE INVENTION

1) Field of the Invention

The present invention relates to a test-pattern generation system, a test-pattern analysis system, a test-pattern generation method, a test-pattern analysis method, a test-pattern generation program, a test-pattern analysis program, and a recording medium for test pattern generation and analysis by using a database in which circuit information, test sequences, test patterns, fault flags, and error conditions are associated with one another.

2) Description of the Related Art

Conventionally, in Automatic Test Pattern Generator (ATPG) in a sequential circuit to be tested, to extract fault activation conditions, the order of test patterns required for signal propagation at the input side of the sequential circuit. The order of test patterns is referred to as a test sequence. It is known that, when test patterns are generated for a fault in a sequential circuit, and if the test sequence of these test patterns is recycled, the processing speed of the ATPG on the sequential circuit can be increased.

Also, in an ATPG of a combinational circuit to be tested, the state of the combinational circuit can be extracted by using a scan flip-flop (FF), and therefore no test sequence is required. However, if a redundant circuit is present in the combination circuit or a circuit to be tested includes an enormous number of back tracks, it takes an enormous amount of time to generate test patterns and the number of test patterns is increased.

Moreover, test patterns generated by the ATPG have to be subjected to Logic simulation to confirm that the test patterns coincide with the operation of the circuit to be tested. If an error occurs in this Logic simulation, the test patterns and the information about the circuit to be tested have to be compared with each other for analysis to specify the cause of the error. However, for a large-sized circuit to be tested, its test patterns and test sequences are complex, and therefore it is difficult to perform analysis. Such a technology is disclosed in, for example, Japanese Patent Laid-Open Publication No. 2000-258511.

However, in the conventional process, the ATPG outputs a test sequence for activating all faults and a test sequence for propagating a fault based on fault flags. Therefore, if part of the circuit to be tested includes a redundant circuit or if activation or propagation conditions are complex, the processing time of the ATPG is increased, and the size of the test patterns is increased.

Furthermore, the test patterns generated by the ATPG do not include the configuration of the circuit to be tested or information about the test sequences. Therefore, when the circuit to be tested is changed after the operation of the ATPG, all test patterns have to be regenerated. Thus, generation of test patterns takes time and effort.

Still further, a problem in the conventional technology disclosed in the above patent document is as follows. In this conventional technology, part of the test patterns is recycled. However, equivalence verification has to be performed on the circuit to be tested, and the ATPG has to be operated to merge the found difference with the generated test pattern. This increases the complexity of updating the processing time and the test patterns.

Still further, conventionally, if Logic simulation performed by using the generated test patterns result in timing error or strobe error, the circuit to be tested has to be analyzed based on the test pattern number, the time when the error occurred in the Logic simulation, and information about the gate where the error occurred to specify the problem.

However, specifying the cause of the error based on these pieces of information is difficult for a large-sized circuit, because it takes a large amount of time and a large number of processes to specify the cause. Also, since knowledge and experiences regarding test designs and circuits are required, it is difficult for beginners to specify the error.

Yet another problem is as follows. In the operation of the ATPG, test patterns are written in a database. However, if test patterns are simultaneously generated by a plurality of CPUs and client terminals and then the database is updated accordingly, a contradiction arises. In yet another problem, a plurality of users cannot change the configuration of the same circuit to be tested or generate test patterns for the same circuit.

In yet another problem, with computer-aided designs (CADs) being created by various manufacturers, what is shared among test pattern generation tools, test pattern analysis tools, and Logic simulators is only a format of part of databases, and databases for use in each tool vary. Therefore, when the process of the ATPG is applied to a CAD created by another manufacturer or when the process results of the ATPG are analyzed by a tool created by another manufacturer, the database have to be converted for use or part of the functions of the database cannot be used.

### SUMMARY OF THE INVENTION

It is an object of the present invention to solve at least the above problems in the conventional technology.

A test-pattern generation system according to one aspect of the present invention includes a net-list input unit that inputs a net list of a circuit; a first terminal-information generating unit that generates, for each terminal included in elements that form the circuit, first terminal information that includes identification information of one of the terminal and propagation route information that indicates identification information of another of the terminal that is located on a signal propagation route to one of the terminal based on the net list; a first fault-detection-information generating unit that generates first-fault detection information for detecting a fault in the terminal for each of the first terminal information generated; a test-sequence-information determining unit that determines whether the first fault-detection information includes identification information of a test sequence; a test-sequence generating unit that generates the test sequence for the first fault-detection information that is determined that the first fault-detection information includes the identification information of the test sequence by the test-sequence-information determining unit; and a test-pattern generating unit that generates a test pattern using the test sequence generated.

A test-pattern analysis system according to another aspect of the present invention includes a net-list input unit that inputs a net list of a circuit; a first terminal-information generating unit that generates, for each terminal included in elements that form the circuit, first terminal information that includes identification information of one of the terminal and propagation route information that indicates identification information of another of the terminal that is located on a signal propagation route to one of the terminal based on the net list; a first fault-detection-information generating unit that generates first-fault detection information for detecting a fault in the terminal for each of the first terminal information generated; a test-sequence-information determining unit that determines whether the first fault-detection information includes identification information of a test sequence; a test-sequence generating unit that generates the test sequence for the first fault-detection information that is determined that the first fault-detection information includes the identification information of the test sequence by the test-sequence-information determining unit; a test-pattern generating unit that generates a test pattern using the test sequence generated; a simulation performing unit that performs a logic simulation on the circuit using the test pattern generated; an obtaining unit that obtains information that includes the test sequence with which the test pattern is generated, the first fault-detection information with which the test sequence is generated, and the fist terminal information of the terminal in which a fault is detected, when a result of the logic simulation includes an error; and an analyzing unit that analyzes the error included in the result using the information obtained.

A test-pattern generation method according to still another aspect of the present invention includes inputting a net list of a circuit; generating, for each terminal included in elements that form the circuit, first terminal information that includes identification information of one of the terminal and propagation route information that indicates identification information of another of the terminal that is located on a signal propagation route to the one of the terminal based on the net list; generating first-fault detection information for detecting a fault in the terminal for each of the first terminal information generated; determining whether the first fault-detection information includes identification information of a test sequence; generating the test sequence for the first fault-detection information that is determined that the first fault-detection information includes the identification information of the test sequence; and generating a test pattern using the test sequence generated.

A test-pattern analysis method according to still another aspect of the present invention includes inputting a net list of a circuit; generating, for each terminal included in elements that form the circuit, first terminal information that includes identification information of one of the terminal and propagation route information that indicates identification information of another of the terminal that is located on a signal propagation route to one of the terminal based on the net list; generating first-fault detection information for detecting a fault in the terminal for each of the first terminal information generated; determining whether the first fault-detection information includes identification information of a test sequence; generating the test sequence for the first fault-detection information that is determined that the first fault-detection information includes the identification information of the test sequence; generating a test pattern using the test sequence generated; performing a logic simulation on the circuit using the test pattern generated; obtaining information that includes the test sequence with which the test pattern is generated, the first fault-detection information with which the test sequence is generated, and the fist terminal information of the terminal in which a fault is detected, when a result of the logic simulation includes an error; and analyzing the error included in the result using the information obtained.

A computer-readable recording medium according to still another aspect of the present invention stores a computer program for realizing a test-pattern generation method according to the above aspect.

A computer-readable recording medium according to still another aspect of the present invention stores a computer program for realizing a test-pattern analysis method according to the above aspect.

The other objects, features and advantages of the present invention are specifically set forth in or will become apparent from the following detailed descriptions of the invention when read in conjunction with the accompanying drawings.

### BRIEF DESCRIPTION OF THE DRAWINGS

FIG. 1 is a block diagram of a schematic configuration of a test pattern generation and analysis system according to one embodiment of the present invention;

FIG. 2 is a block diagram of a hardware configuration of a database server and a work station shown in FIG. 1;

FIG. 3 is a block diagram of a functional configuration of the test pattern generation and analysis system according to one embodiment of the present invention;

FIG. 4 is a block diagram of an example of a circuit targeted for test pattern generation and analysis of the test pattern generation and analysis system according to the embodiment of the present invention;

FIG. 5 is a drawing for explaining a node information table recorded on a node-information-table storage unit shown in FIG. 3;

FIG. 6 is a drawing of an element type table stored in an element-type-ID storage unit shown in FIG. 3;

FIG. 7 is a drawing for explaining a fault flag table stored in a fault-flag-table storage unit shown in FIG. 3;

FIG. 8 is a drawing for explaining a test sequence table stored in a test-sequence-table storage unit shown in FIG. 3;

FIG. 9 is a drawing for explaining a test pattern table stored in a test-pattern-table storage unit shown in FIG. 3;

FIG. 10 is a block diagram depicting one example of a target circuit for explaining an activation test sequence and a propagation sequence;

FIG. 11 is a flowchart of a procedure of a test-sequence and test-pattern generating process according to the embodiment of the present invention;

FIG. 12 is a drawing for explaining a node information table generated for a target circuit shown in FIG. 4;

FIG. 13 is a flowchart of a specific procedure of a fault-flag-table generating process (step S1103) shown in FIG. 11;

FIG. 14 is a drawing of examples of fault flag tables generated through the fault-flag-table generating process;

FIG. 15 is a first flowchart of a specific procedure of a test-sequence-table and test-pattern-table generating process (step S1104) shown in FIG. 11;

FIG. 16 is a drawing of an example of extraction of a fault flag table;

FIG. 17 is a drawing of an example of extraction of a node information table;

FIG. 18 is a second flowchart of the specific procedure of the test-sequence-table and test-pattern-table generating process (step S1104) shown in FIG. 11;

FIG. 19 is a drawing for explaining an example of extraction at step S1802 of a node information table with a node ID on propagation routes;

FIG. 20 is a drawing for explaining an example of extraction at step S1804 of a test sequence table;

FIG. 21 is a drawing for explaining an example of an ATPG process to be performed by using the test sequence table extracted as shown in FIG. 20;

FIG. 22 is a drawing for explaining association of a node information table with a test sequence table and a test pattern table;

FIG. 23 is a flowchart of a procedure of a database updating process according to the embodiment of the present invention;

FIG. 24 is a flowchart of a specific procedure of a deleting process shown in FIG. 23;

FIG. 25 is a block diagram of one example of a target circuit;

FIG. 26 is a table of a correspondence between node names and node IDs for the target circuit shown in FIG. 25;

FIG. 27 is a schematic drawing that depicts a process of deleting an element in the target circuit shown in FIG. 25;

FIG. 28 is a block diagram of another example of the target circuit;

FIG. 29 a table of a correspondence between node names and node IDs for the target circuit shown in FIG. 28;

FIG. 30 is a first schematic drawing that depicts a process of deleting an element in the target circuit shown in FIG. 28;

FIG. 31 is a second schematic drawing that depicts the process of deleting an element in the target circuit shown in FIG. 28;

FIG. 32 is a third schematic drawing that depicts the process of deleting an element in the target circuit shown in FIG. 28;

FIG. 33 is a first flowchart of a specific procedure of a changing process shown in FIG. 23;

FIG. 34 is a second flowchart of the specific procedure of the changing process shown in FIG. 23;

FIG. 35 is a flowchart of a specific procedure of an adding process shown in FIG. 23;

FIG. 36 is a flowchart of a procedure of a test pattern analyzing process of a test pattern generation and analysis device according to one embodiment of the present invention;

FIG. 37 is a schematic diagram of a test pattern analyzing process shown in FIG. 36;

FIG. 38 is a drawing of waveforms obtained through a waveform analysis tool;

FIG. 39 is a circuit diagram displayed by a circuit diagram displaying tool; and

FIG. 40 is a drawing for explaining a transaction process in the test pattern generation and analysis system according to one embodiment of the present invention.

### DETAILED DESCRIPTION

With reference to the attached drawings, exemplary embodiments of a test-pattern generation system, a test-pattern analysis system, a test pattern generation device, a test pattern analysis device, a test-pattern generation method, a test-pattern analysis method, a test-pattern generation program, a test-pattern analysis program, and a recording medium therefor according to the present invention are described in detail below.

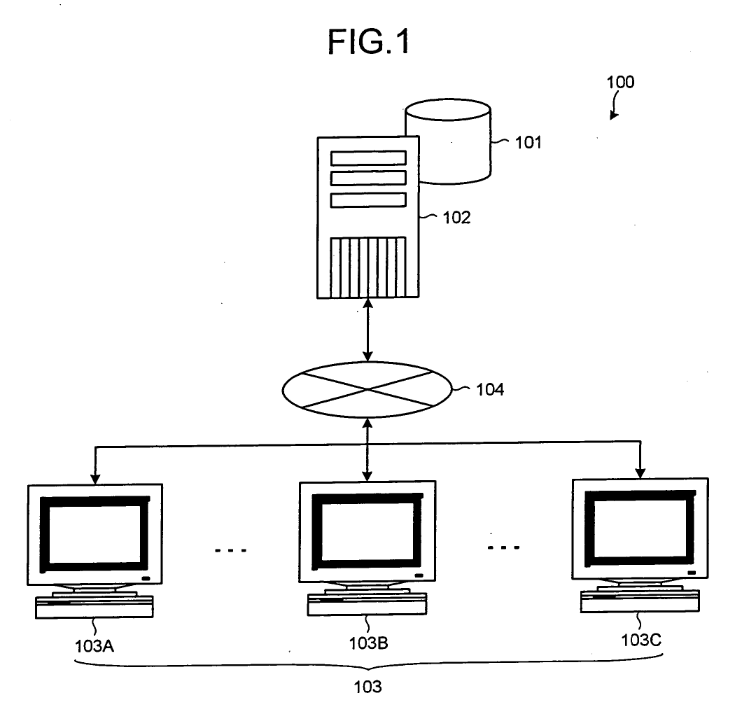

First, a schematic configuration of the test pattern generation and analysis system according to one embodiment of the present invention is described. FIG. 1 is a block diagram of the test pattern generation and analysis system according to one embodiment of the present invention. In a test pattern generation and analysis system 100 shown in FIG. 1, a database server 102 including a database 101 and a plurality of work stations 103 (103A to 103C) are communicably connected to one another via a network 104, such as a LAN or the Internet.

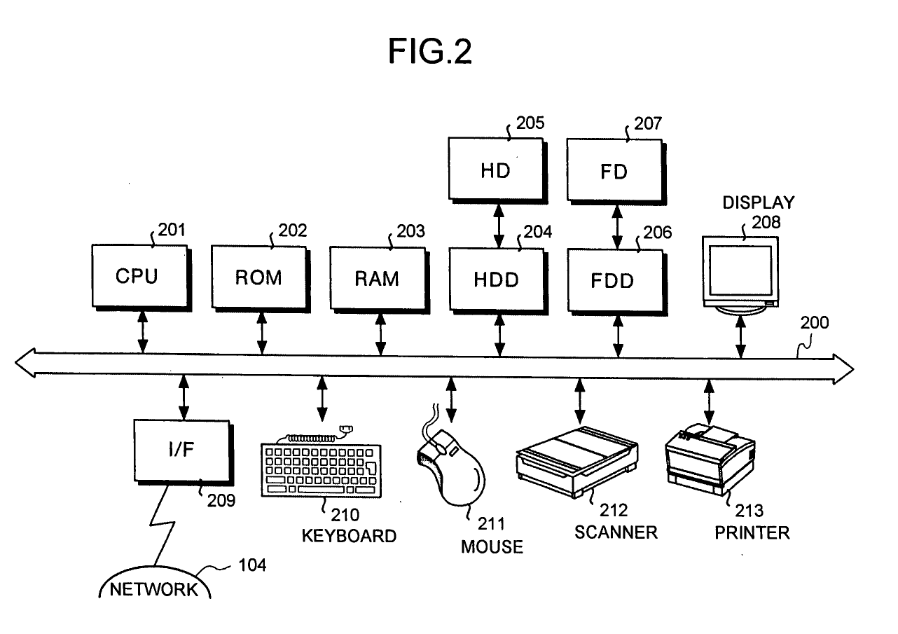

Next, the hardware structure of the database server 102 and the work station 103 shown in FIG. 1 is described. FIG. 2 is a block diagram of the hardware structure of the database server 102 and the work station 103 shown in FIG. 1.

In FIG. 2, the database server 102 and the work station 103 each include a CPU 201, a ROM 202, a RAM 203, a hard disk drive (HDD) 204, a hard disk (HD) 205, a flexible disk drive (FDD) 206, a flexible disk (FD) 207, which is an example of a removable recording medium, a display 208, an interface (I/F) 209, a keyboard 210, a mouse 211, a scanner 212, and a printer 213. Also, these components are connected one another via a bus 200.

Here, the CPU 201 controls over the entire database server 102 and the work station 103. The ROM 202 stores a program, such as a boot program. The RAM 203 is used as a work area for the CPU 201. The HDD 204 controls any one or both of read and write of the data with respect to the HD 205 under the control of the CPU 201. The HD 205 stores data written under the control of the HDD 204.

The FDD 206 controls any one or both of read and write of the data with respect to the FD 207 under the control of the CPU 201. The FD 207 stores data written under the control of the FDD 206, and causes data stored in the FD 207 to be read by the database server 102 and the work station 103.

An example of the removable recording medium may be the FD 207, a CD-ROM (CD-R, CD-RW), magnet optical (MO) disk, Digital Versatile Disk (DVD), or memory card. The display 208 displays data, such as a cursor, an icon, tool box, text, image, function information, and the like. For possible adoption as this display 208, a cathode-ray tube (CRT), thin-film transistor (TFT) liquid crystal display, plasma display, or the like can be considered.

The I/F 209 is connected via a communication line to the network 104, such as the Internet and, through this network 104, is connected to another device. The I/F 209 serves as an interface between the network 104 and the inside for controlling inputs and outputs of data from external devices. For possible adoption as the I/F 209, a modem, a local-area network (LAN) adaptor, or the like can be considered.

The keyboard 210 includes keys for input of characters, numbers, various instruction, and the like, and is used to provide inputs of data. Alternatively, a touch-panel-type input pad or ten keys may suffice for the purpose. The mouse 211 is used to move a cursor, select a range, move a window, or change the size of the window, for example. Alternatively, a track ball or joystick may suffice for the purpose as long as it similarly functions as a pointing device.

The scanner 212 optically reads images, and causes image data to be captured in the database server 102 and the work station 103. The scanner 212 may have an optical character recognition (OCR) function. Also, the printer 213 prints image data and text data. For possible adoption as the printer 213, a laser printer and ink jet printer can be considered.

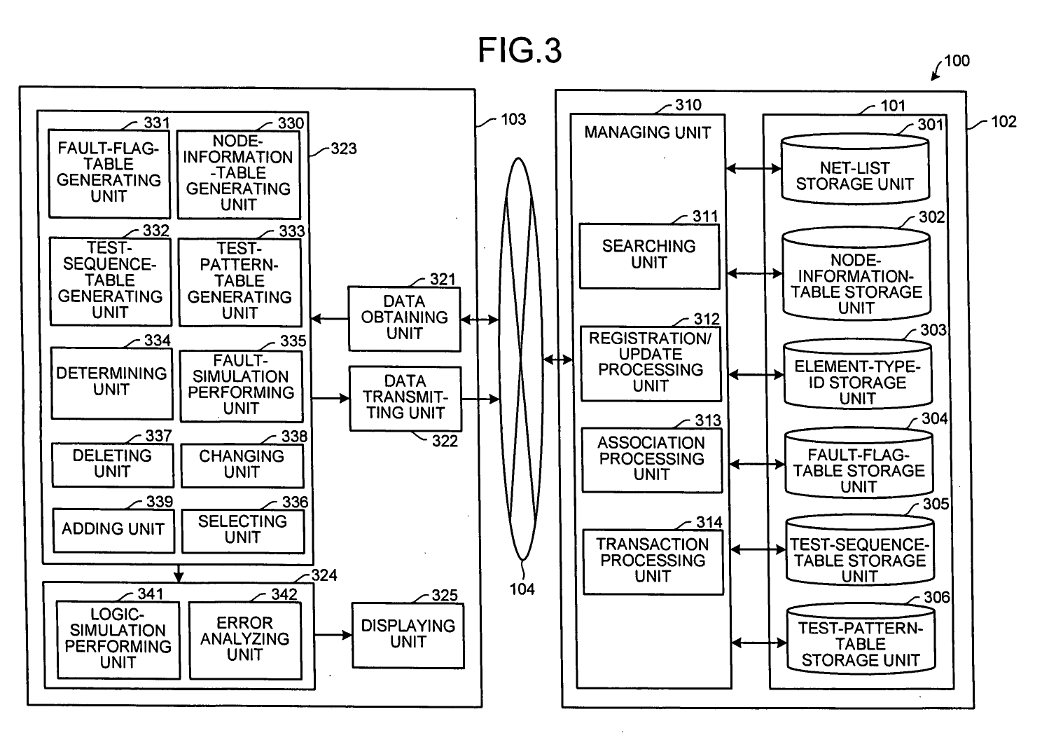

Next, the functional configuration of the test pattern generation and analysis system 100 according to the embodiment of the present invention is described. FIG. 3 is a block diagram of the functional configuration of the test pattern generation and analysis system according to the embodiment of the present invention. In FIG. 3, the test pattern generation and analysis system 100 includes the database server 102 and the work station 103 that are communicably connected to one another via the network 104.

The database server 102 includes the database 101 and a managing unit 310. The database 101 stores a net list storage unit 301, a node-information-table storage unit 302, an element-type-ID storage unit 303, a fault-flag-table storage unit 304, a test-sequence-table storage unit 305, and a test-pattern-table storage unit 306.

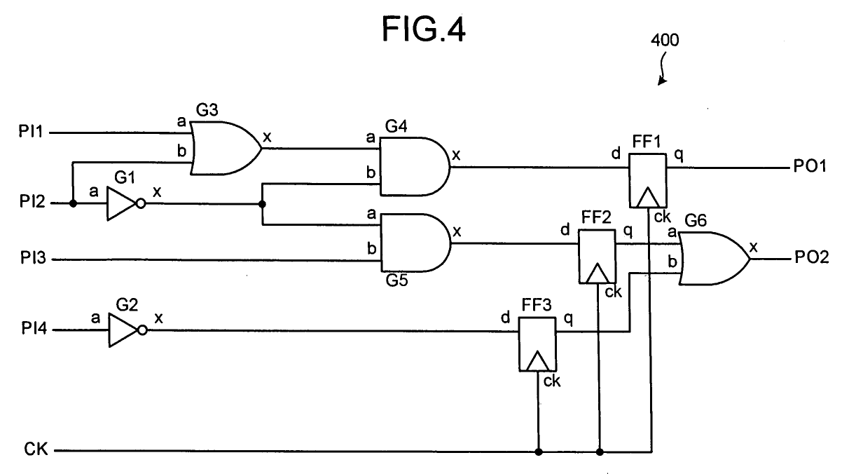

The net list storage unit 301 stores a net list for a target circuit, such as information about elements forming the target circuit, terminals (also referred to as nodes) of the elements, a connection relation among the nodes. Here, the target circuit is specifically described as an example. FIG. 4 is a block diagram of an example of a circuit targeted for test pattern generation and analysis of the test pattern generation and analysis system 100 according to the embodiment of the present invention.

In FIG. 4, a circuit (target circuit) 400 targeted for test pattern generation and analysis of the test pattern generation and analysis system 100 includes input terminals PI1 to PI4, a clock terminal CK, output terminals PO1 and PO2, an OR circuit G3 receiving inputs of signals from the input terminals PI1 and PI2, an inverter G1 receiving an input of a signal from the input terminal PI2, an AND circuit G4 receiving inputs of signals from the OR circuit G3 and the inverter G1, a sequential circuit FF1 receiving inputs of an output signal from the AND circuit G4 and a clock signal from the clock terminal CK and outputting these signals to the output terminal PO1, an AND circuit G5 receiving inputs of signals from the input terminal PI2 and the inverter G1, a sequential circuit FF2 receiving inputs of a signal from the AND circuit G5 and a clock signal from the clock terminal CK, an inverter G2 receiving an input of a signal from the input terminal PI4, a sequential circuit FF3 receiving inputs of a signal from the inverter G2 and a clock signal from the clock terminal CK, and an OR circuit G6 receiving inputs of signals from the sequential circuit FF2 and the sequential circuit FF3 and outputting these signals to the output terminal PO2.

Also, in the target circuit 400, as for an element forming the target circuit 400 and having no lower-case letter, the reference character of that element represents a node name. For example, reference characters provided to the input terminals PI1 to PI4, the clock terminal CK, and the output terminals PO1 and PO2 represent names of nodes stored in a node information table, which will be described further below.

On the other hand, as for an element forming the target circuit 400 and having a lower-case letter provided to its terminal, the reference character and the lower-case letter of that element represent a node name. For example, as for the OR circuit G3, its input terminal “a” represents a node “G3.a”, its input terminal “b” represents a node “G3.b”, its output terminal “x” represents a node “G3.x”. The same goes for other elements.

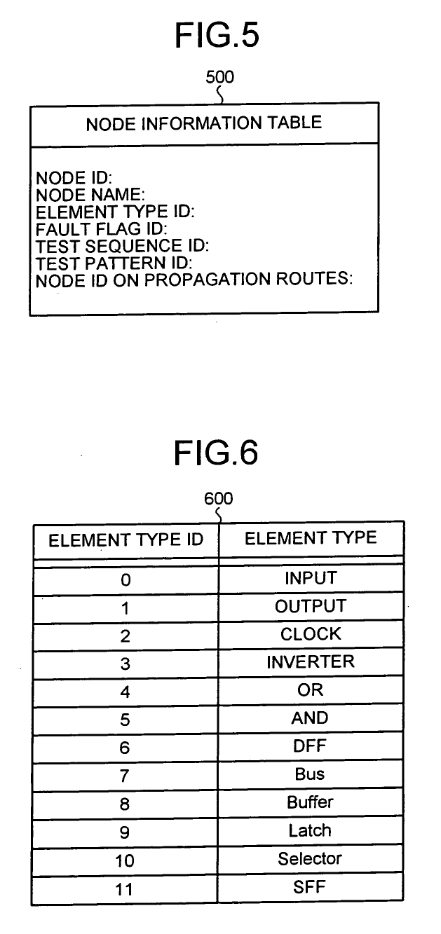

Also, in FIG. 3, the node-information-table storage unit 302 stores node information tables regarding the nodes of the target circuit 400. Here, a node information table is described. FIG. 5 is a drawing for explaining the node information table recorded on the node-information-table storage unit 302 shown in FIG. 3. In FIG. 5, a node information table 500 includes node ID, node name, element type ID, fault flag ID, test sequence ID, test pattern ID, and node ID on propagation routes.

The “node ID” has stored therein a numerical value serving as a key for identifying the node information table 500. This numerical value represents an ordinal number in which the node information table 500 was generated. The “node name” has stored therein a node name, which has been described above. The “element type ID” has stored therein an ID number of an element type representing the type of the element including the node represented by the name stored in the “node name”. The “fault flag ID” has stored therein an ID number of a fault flag table, which will be described further below. The “test sequence ID” has stored therein an ID number of a test sequence table, which will be described further below. The “test pattern ID” has stored therein an ID number of a test pattern table, which will be described further below.

The “node ID on propagation routes” has stored therein ID numbers of other elements on signal propagation routes to the node specified by the “node name”. For example, as for the node G4.a, signal propagation routes to the node G4.a are:
(1) node PI1→node G3.a→node G3.x→node G4.a; and
(2) node PI2→node G3.b→node G3.x→node G4.a.

Therefore, other elements or nodes located on these signal propagation routes (1) and (2) are “node PI1”, “node PI2”, “node G3.a”, “node G3.b”, and “node G3.x”. ID numbers of these nodes are stored in the “node ID on propagation route”.

Also, for example, as for the node G4.x, signal propagation routes to the node G4.x are:
(3) node PI1→node G3.a→node G3.x→node G4.a→node G4.x;
(4) node PI2→node G3.b→node G3.x→node G4.a→node G4.x; and
(5) node PI2→node G1.a→node G1.x→node G4.b→node G4.x.

Therefore, other elements or nodes located on these signal propagation routes (3), (4), and (5) are “node PI1”, “node PI2”, “node G3.a”, “node G3.b”, “node G3.x”, “node G1.a”, and “node G1.x”. ID numbers of these nodes are stored in the “node ID on propagation route”. Since the node G4.x represents an output terminal of an element G4, the “node G4.a” and the “node G4.b” representing terminals included in the element G4 are not included in other element's nodes located on the signal propagation routes (3) to (5).

Furthermore, in FIG. 3, the element-type-ID storage unit 303 stores a type of the element of the target circuit 400 and an element type ID (ID number) of the corresponding type of the element. The element type ID is recorded on the node information table described above. FIG. 6 is a drawing of the element type table stored in the element-type-ID storage unit 303 shown in FIG. 3. In FIG. 6, in an element type table 600, each element type ID is associated with an element type.

Specifically, an element type ID of “0” is associated with an element type of “INPUT” representing an input terminal. An element type ID of “1” is associated with an element type of “OUTPUT” representing an output terminal. An element type of “2” is associated with an element type of “CLOCK” representing a clock terminal. An element type of “3” is associated with an element type of “INVERTER” representing an inverter.

An element type of “4” is associated with an element type of “OR” representing an OR circuit. An element type of “5” is associated with an element type of “AND” representing an AND circuit. An element type of “6” is associated with an element type of “DEF” representing a D flip-flop circuit. An element type of “7” is associated with an element type of “Bus” representing a bus.

An element type of “8” is associated with an element type of “Buffer” representing a buffer. An element type of “9” is associated with an element type of “Latch” representing a latch circuit. An element type of “10” is associated with an element type of “Selector” representing a selector circuit. An element type of “11” is associated with an element type of “SFF” representing an SR flip-flop circuit.

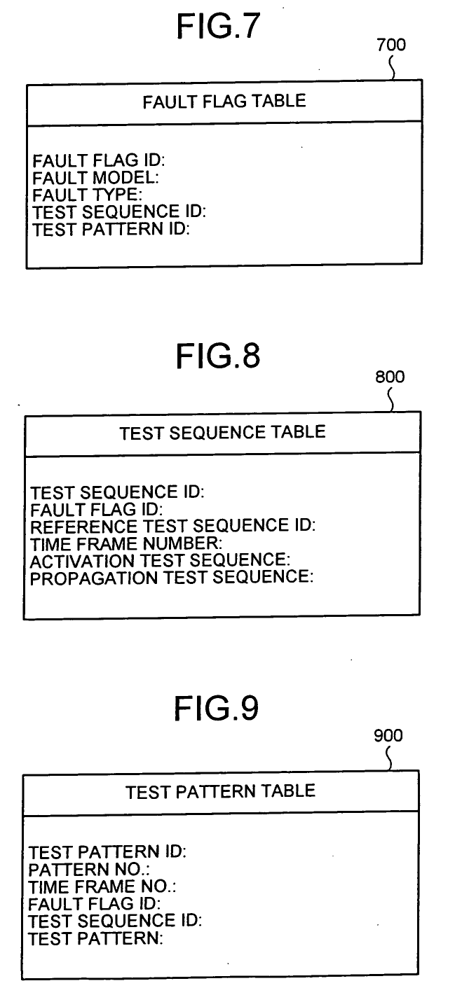

Still further, in FIG. 3, the fault-flag-table storage unit 304 stores fault flag tables. Here, a fault flag table stored in the fault-flag-table storage unit 304 shown in FIG. 3 is described. FIG. 7 is a drawing for explaining the fault flag table stored in the fault-flag-table storage unit 304 shown in FIG. 3. In FIG. 7, a fault flag table 700 includes a fault flag ID, fault model, fault type, test sequence ID, and test pattern ID.

The “fault flag ID” has stored therein a numerical value serving as a key for identifying the fault flag table. This numerical value is provided in the order of generation of fault flag tables. The “fault model” has stored therein a name of a fault model, such as “stuck-at fault” or “transition fault”. The “fault type” has stored therein a name representing a type of the “fault model”. For example, when the “fault model” is a “stuck-at fault”, the “fault type” has stored therein either one of “s-a-0” representing 0 struck-at fault and “s-a-1” representing 1 struck-at fault.

The “test sequence ID” has stored therein, as with the node information table shown in FIG. 5, an ID number of a test sequence table, which will be described further below. The “test pattern ID” has stored therein, as with the node information table shown in FIG. 5, an ID number of a test pattern table, which will be described further below.

Still further, in FIG. 3, the test-sequence-table storage unit 305 stores test sequence tables. Here, a test sequence table stored in the test-sequence-table storage unit 305 shown in FIG. 3 is described.

FIG. 8 is a drawing for explaining the test sequence table stored in the test-sequence-table storage unit 305 shown in FIG. 3. In FIG. 8, a test sequence table 800 includes a test sequence ID, fault flag ID, reference test sequence ID, a time frame number, activation test sequence, and propagation test sequence.

The “test sequence ID” has stored therein a numerical value serving as a key that can identify the test sequence table. This numerical value is provided in the order of generation of test sequence tables. The “fault flag ID” has stored therein, as with the fault flag table shown in FIG. 7, an ID number of a fault flag table. The “reference test sequence ID” has stored therein an ID number of a test sequence referred to when the test sequence 800 is generated.

The “time frame number” has stored therein a number representing an ordinal number in which the test sequence is input. The “activation test sequence” has stored therein an input test pattern that can activate the fault, that is that can detect the fault. The “propagation test sequence” as stored therein an input test pattern that causes the fault activated (detected) by the activation test sequence to propagate, that is an input test pattern that cannot detect the fault.

Still further, the test-pattern-table storage unit 306 stores the test pattern table. Here, a test pattern table stored in the test-pattern-table storage unit 306 shown in FIG. 3 is described.

FIG. 9 is a drawing for explaining the test pattern table stored in the test-pattern-table storage unit 306 shown in FIG. 3. In FIG. 9, a test pattern table 900 includes a test pattern ID, pattern number, time frame number, fault flag number, test sequence ID, and test pattern.

The “test pattern ID” has stored therein a numerical value serving as a key for identifying the test pattern table 900. This numerical value represents an ordinal number in which the test pattern table 900 was generated. The “pattern number” has stored therein a number provided to the test pattern. Since several test patterns are used in combination, the pattern number represents an ordinal number to the relevant test pattern. This is used to search for and indicate a number provided to a test pattern in which the error occurred at the time of analyzing the results of logic simulation.

The “time frame number” has stored therein a number (time frame number) representing an ordinary number of input of the test pattern. The “test sequence ID” has stored therein an ID number of the test sequence corresponding to the test pattern. The “test pattern” has stored therein a test pattern including a test sequence representing an input test pattern and an expected value (output test pattern) obtained when ATPG is executed by using this test sequence. With association of the tables shown in FIGS. 5 to 9, part of data is updated and, simultaneously, the associated contents of these tables are updated.

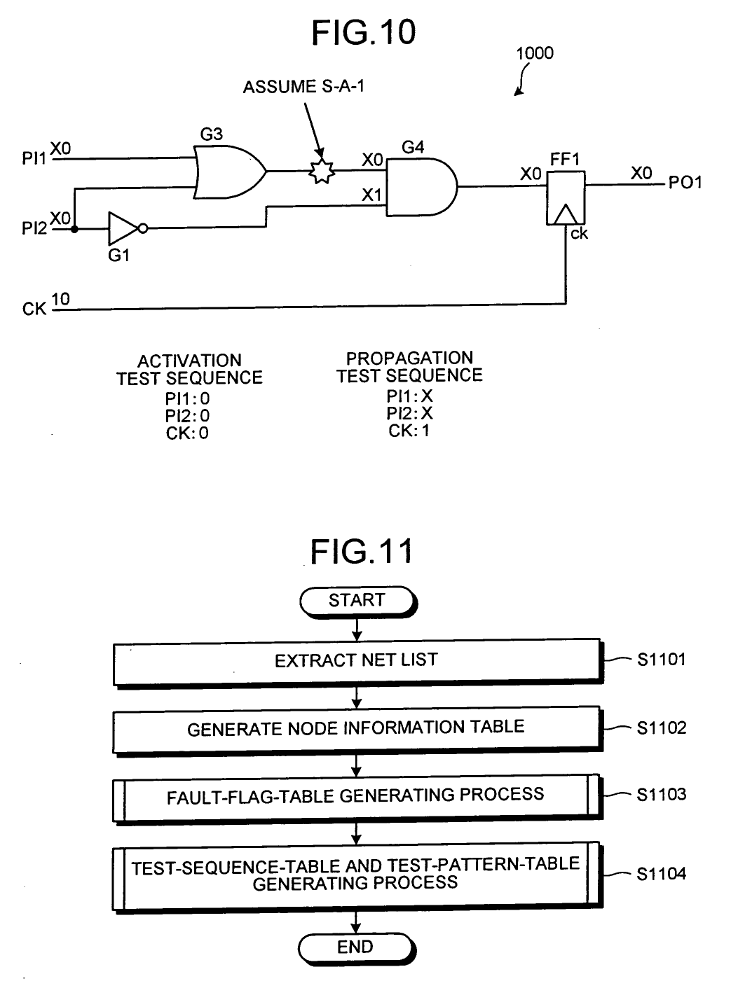

Next, the activation test sequence and the propagation test sequence described above are specifically described. FIG. 10 is a block diagram depicting one example of a target circuit for explaining the activation test sequence and the propagation sequence. Since this target circuit 1000 is a part of the target circuit shown in FIG. 4, elements identical to the elements shown in FIG. 4 are provided with the same reference characters.

This target circuit 1000 includes the input terminals PI1 and P12, the clock terminal CK, the output terminal P01, the OR circuit G3 receiving inputs of signals from the input terminals PI1 and PI2, the inverter G1 receiving an input of a signal from the input terminal PI2, the AND circuit G4 receiving inputs of signals from the OR circuit G3 and the inverter G1, and the sequential circuit FF1 receiving inputs of an output signal from the AND circuit G4 and a clock signal from the clock terminal CK and outputting these signals to the output terminal P01.

Here, in the target circuit 1000, an activation test sequence is found. For example, when it is assumed that an output of the OR circuit G3 is a stuck-at fault (S-A-1), “0” is not output from the OR circuit G3; Therefore, an output of the output terminal PO0 is an error, and thus a fault is detected. In this case, an activation test sequence (PI1, PI2, ck) becomes (PI1, PI2, ck)=(0, 0, 0). On the other hand, a test pattern in which no fault is detected is referred to as “sequence that allows fault propagation”. In this circuit, the propagation sequence (PI1, PI2, ck) becomes (PI1, PI2, ck)=(X, X, 1).

The net list storage unit 301, the node-information-table storage unit 302, the element-type-ID storage unit 303, the fault-flag-table storage unit 304, the test-sequence-table storage unit 305, and the test-pattern-table storage unit 306 achieve the respective functions specifically by, for example, the ROM 202, the RAM 203, the HD 205, the FD 207, and the like shown in FIG. 2, for example.

Also, in FIG. 3, the managing unit 310 includes a searching unit 311, a registration/update processing unit 312, an association processing unit 313, and a transaction processing unit 314. The searching unit 311 responds to a search request from a work station 103 (a test pattern generation and analysis device) to search a desired net list or table from the database 101 for transmission to the work station 103 (the test pattern generation and analysis device) that issued the search request.

The registration/update processing unit 312 registers a table newly generated by the work station 103 (the test pattern generation and analysis device) in the database 101, or updates a table with its table contents being changed.

The association processing unit 313 associates the node information table 500, the fault flag table 700, the test sequence table 800, and the test pattern table 900 with one another. Specifically, the association processing unit 313 records the fault flag ID, the test sequence ID, and the test pattern ID on the node information table 500, stores the test sequence ID and the test pattern ID in the fault flag table 700, and stores the fault flag ID and the test sequence ID in the test pattern table 900.

The transaction processing unit 314 performs a transaction process on the work station 103 (the test pattern generation and analysis device), such as, specifically, a roll-back process, a commit process, lock-and-unlock control, or failure recovery management.

Also, the work station 103 (the test pattern generation and analysis device) includes a data obtaining unit 321, a data transmitting unit 322, a table generating unit 323, an analyzing unit 324, and a displaying unit 325. The data obtaining unit 321 issues a request for obtaining a net list and data, thereby receiving inputs of a net list and various tables extracted by the database server 102. The data transmitting unit 322 transmits a table generated by the table generating unit 323 to the database server 102.

The table generating unit 323 includes a node-information-table generating unit 330, a fault-flag-table generating unit 331, a test-sequence-table generating unit 332, a test-pattern-table generating unit 333, a determining unit 334, a fault-simulation performing unit 335, a selecting unit 336, a deleting unit 337, a changing unit 338, and an adding unit 339.

The node-information-table generating unit 330 generates, for each terminal (node) included in an element forming the target circuit, the node information table 500 shown in FIG. 5 based on the received net list. The fault-flag-table generating unit 331 generates, for each node information table 500, the fault flag table 700 for detecting a fault in the node.

The test-sequence-table generating unit 332 generates, through an Automatic Test Pattern Generator (ATPG), test sequences including an activation test sequence for activating a fault in the node and a propagation test sequence for propagating a fault in the activation test sequence, and then generates the test sequence table 800 including the generated test sequences (refer to FIG. 8).

The test-pattern-table generating unit 333 uses the test sequences generated by the test-sequence-table generating unit 332 to generate test patterns through the ATPG, and then generates the test pattern table 900 including the generated patterns (refer to FIG. 9).

The determining unit 334 decides whether the table to be targeted includes a desired ID. Specifically, the determining unit 334 decides whether the fault flag table 700 includes the test sequence IDs of the test sequences including the activation test sequence for activating a fault in the node and the propagation test sequence for propagating a fault in the activation test sequence.

The determining unit 334 also decides whether the node information table 500 specified by the node ID recorded on the fault flag table 700 decided as not including a test sequence ID includes a node ID on the propagation routes. Furthermore, the determining unit 334 decides whether the fault flag table to be targeted includes a fault flag table serving as an equivalent fault.

The fault-simulation performing unit 335 is a fault simulator, for example, to perform a simulation for checking whether a fault occurs in the target circuit by using the generated test patterns. The selecting unit 336 accepts, in element deletion mode or element change mode, selection of an arbitrary element from the target circuit. Also, the selecting unit 336 accepts selection of a position where an element other than the elements forming the target circuit is to be added.

The deleting unit 337 deletes the node information table 500 of the node included in the element selected by the selecting unit 336. This deletion is based on the decision result by the determining unit 334 regarding the presence or absence of an equivalent fault. The changing unit 338 changes the node information table 500 of the node included in the element selected by the selecting unit 336 to a newly generated node information table. This change is based on the decision result by the determining unit 334 regarding the presence or absence of an equivalent fault. The adding unit 339 adds a node ID for identifying a node of an element to be added at the position selected by the selecting unit 336 to the node ID on the propagation routes in the generated node information table 500.

The analyzing unit 324 includes the logic-simulation performing unit 341 and an error analyzing unit 342. The logic-simulation performing unit 341 is a logic simulator that performs a logic simulation for the target circuit by using the generated test patterns. The error analyzing unit 342 analyzes (decides) whether the result of the logic simulation has an error. If the result has an error, the error analyzing unit 342 extracts various tables, and then outputs error analysis results to the displaying unit 325. The displaying unit 325 displays the error analysis results.

The managing unit 310, the data obtaining unit 321, the data transmitting unit 322, the table generating unit 323, and the analyzing unit 324 achieve their functions with a program stored in the ROM 202, the RAM 203, the HD 205, the FD 207, or the like being executed by the CPU 201, or with the I/F 209.

Next, a procedure of the test-sequence and test-pattern generating process according to the present embodiment is described. FIG. 11 is a flowchart of a procedure of a test-sequence and test-pattern generating process according to the embodiment of the present invention. In FIG. 11, firstly, an arbitrary net list is extracted from the net list storage unit 301 (step S1101). Then, using the extracted net list, a node information table is generated (step S1102). Next, a fault-flag-table generating process is performed (step S1103). Lastly, the test-sequence-table and test-pattern-table generating process is performed (step S1104).

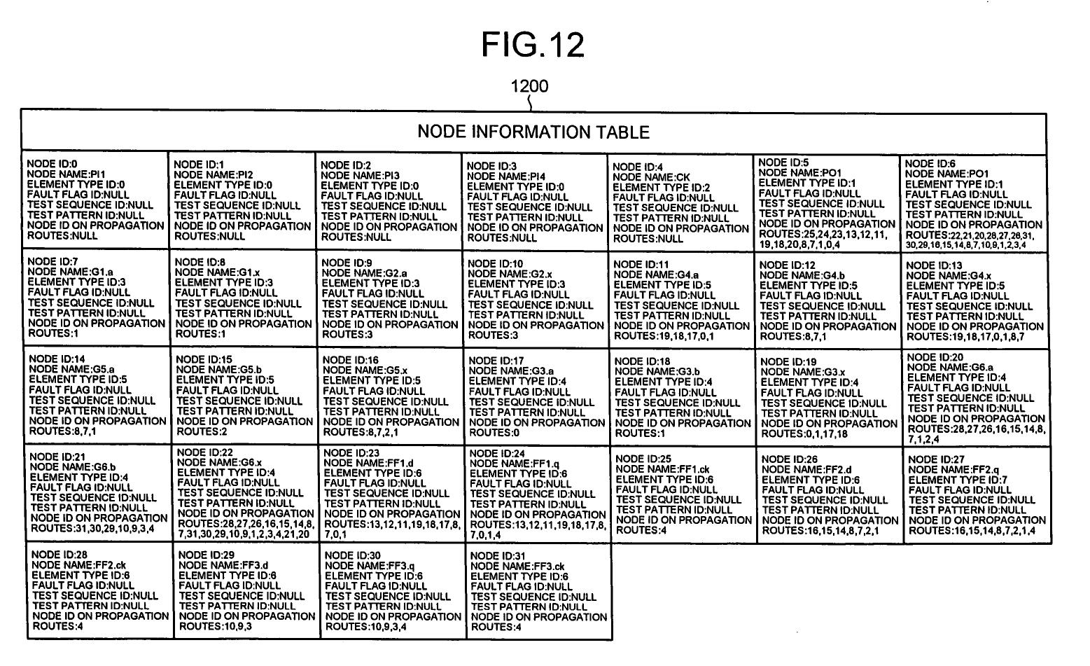

Here, a node information table generated for the target circuit 400 shown in FIG. 4 is described. FIG. 12 is a drawing for explaining the node information table generated for the target circuit 400 shown in FIG. 4. In FIG. 12, a node information table 1200 is generated as many as the number of elements included in the target circuit. The “fault flag ID”, “test sequence ID”, and “test pattern ID” have described therein NULL (indicative of absence) in an initial state. The node information table is updated when the tables shown in FIGS. 7 to 9 are generated.

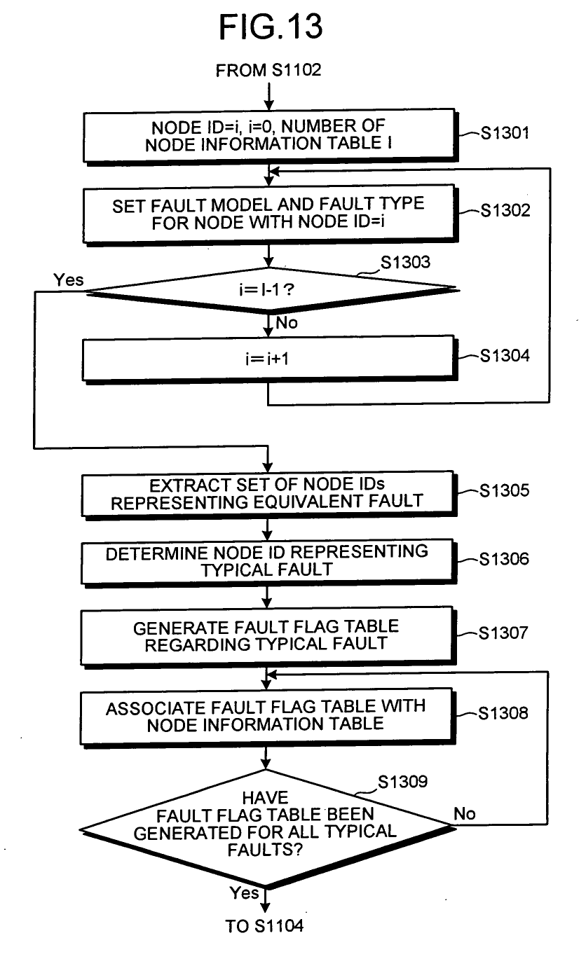

Next, a specific procedure of a fault-flag-table generating process (step S1103) shown in FIG. 11 is described. FIG. 13 is a flowchart of the specific procedure of the fault-flag-table generating process (step S1103) shown in FIG. 11. In FIG. 13, the number of node information tables generated at step S1102 is taken as I, the node ID is taken as ID=i, and an initial value of i is set as i=0 (step S1301).

Next, as for the node with the node ID=i, a fault model and a fault type are set (step S1302). When i is not I-1 (step S1303: No), i is incremented (step S1304) and the procedure goes to step S1302. On the other hand, when i=1-1 (step S1303: Yes), a set of node IDs representing an equivalent fault is extracted (step S1305).

Then, form the extracted set of the ID nodes, a node ID representing a typical fault is decided (step 1306). Then, for the typical fault, a fault flag table is generated (step S1307). Then, the generate fault flag table is associated with the node information table (step S1308). Specifically, the fault flag ID of the fault flag table generated at step S1307 is written in the node information table of the node ID representing the typical fault decided at step S1306.

Then, when fault flag tables have not yet been generated for all nodes ID representing typical faults (step S1309: No), the procedure goes to step S1308. On the other hand, when fault flag tables have been generated for all nodes ID representing typical faults (step S1309: Yes), the procedure goes to step S1104 shown in FIG. 11.

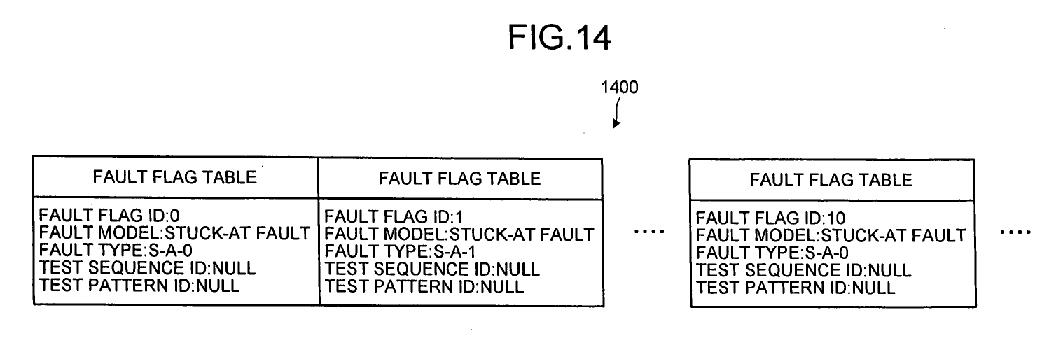

Through this fault-flag-table generating process, the fault flag tables are generated. FIG. 14 is a drawing of examples of fault flag tables generated through the fault-flag-table generating process. In these fault flag tables 1400 shown in FIG. 14, a stuck-at fault is set as the fault model, and S-A-1 or S-A-0 is set as the fault type. At this time, no test sequence table or test pattern table is generated. Therefore, the “test sequence ID” and “test pattern ID” are “NULL”.

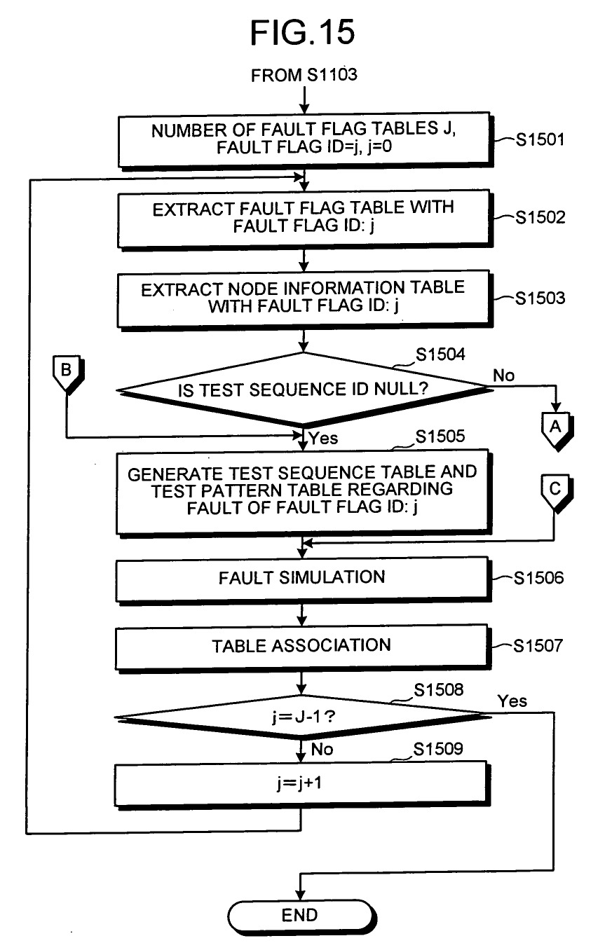

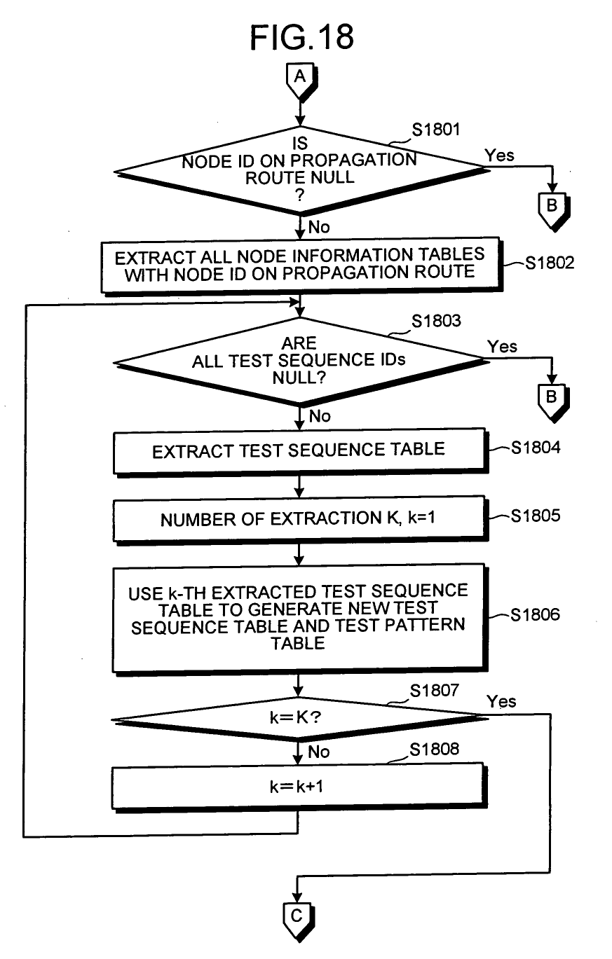

Next, a specific procedure of a test-sequence-table and test-pattern-table generating process (step S1104) shown in FIG. 11 is described. FIGS. 15 and 18 are flowcharts of the specific procedure of the test-sequence-table and test-pattern-table generating process (step S1104) shown in FIG. 11. In FIG. 15, the number of fault flag tables generated at step S1103 is set as J, the fault flag ID=j, and an initial value of j is set as j=0 (step S1501).

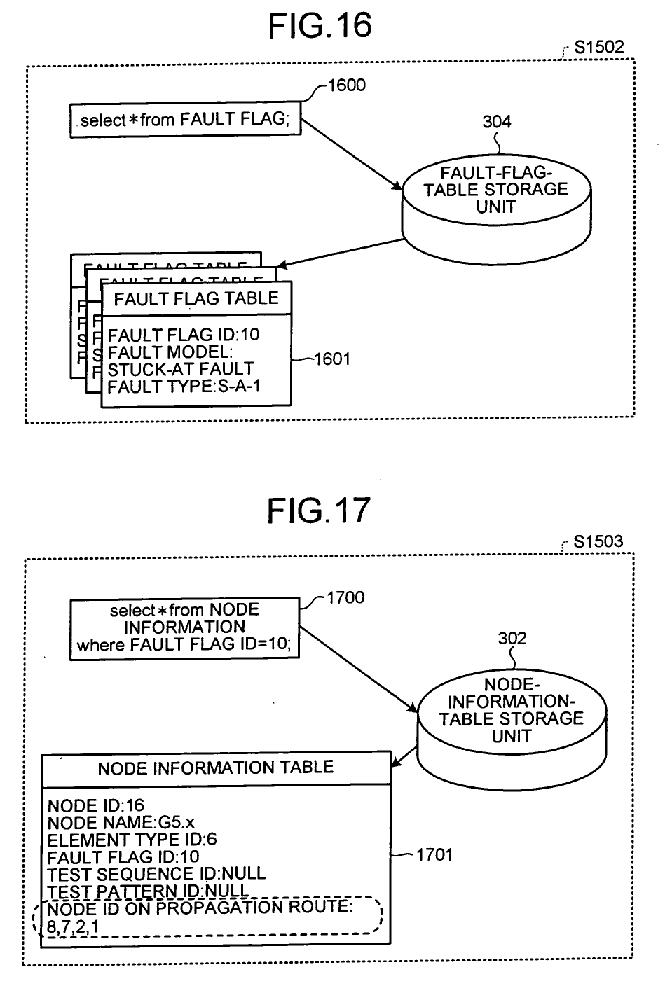

Then, from the fault-flag-table storage unit 304, a fault flag table with its fault flag ID: j is extracted (step S1502). FIG. 16 is a drawing of an example of extraction of a fault flag table. In FIG. 16, a structured-query-language (SQL) syntax 1600 is used to extract fault flag tables 1601 with their fault flag ID: 10 from the fault-flag-table storage unit 304. These fault flag tables 1601 with their fault flag ID: 10 represent one stuck-at fault.

Also, a node information table with their fault flag ID: j is extracted from the node-information-table storage unit 302 (step S1503). FIG. 17 is a drawing of an example of extraction of a node information table. In FIG. 17, an SQL syntax 1700 is a syntax for extracting, from the node-information-table storage unit 302, a node information table corresponding to the fault flag tables shown in FIG. 16.

That is, from the node-information-table storage unit 302, a node information table 1701 with its fault flag ID having recorded thereon “10” is extracted. The node name recorded on this node information table 1701 is “G5.x”. Therefore, FIGS. 16 and 17 depict that the target fault of the element G5 shown in FIG. 4 is the fault flag table 1601 with its fault flag ID: 10.

Then, in FIG. 15, it is decided whether the test sequence ID of the fault flag table 1601 extracted at step S1502 is NULL (step S1504). A process when the test sequence ID is not NULL (step S1504: No) will be described further below with reference to FIG. 18. When the test sequence ID is NULL (step S1504: Yes), the ATPG is used to generate a test sequence table and a test pattern table regarding the fault of the fault flag ID: j (step S1505).

Specifically, an activation test sequence for activating the fault of the fault flag ID: j and a propagation test sequence for propagating the activation test sequence are generated by the ATPG. Then, a test sequence table having recorded thereon the generated activation test sequence and propagation test sequence is generated. Similarly, the generated activation test sequence and propagation test sequence are used to generate test patterns, and a test pattern table having recorded thereon the generated test patterns is generated.

Next, with the generated test patterns being given to the fault simulator, a fault simulation of the target circuit shown in FIG. 4 is performed (step S1506) to check whether a fault has been detected. Then, the fault flag table with its fault flag ID: j, the node information table having recorded thereon the fault flag ID: j, and the generated test sequence table and test pattern table are associated with one another (step S1507).

Specifically, the test sequence ID of the test sequence table and the test pattern ID of the test pattern table, these tables being generated at step S1505, are recorded on the fault flag table with its fault flag ID: j and the node information table having recorded thereon the fault flag ID: j. Also, a fault flag ID of “10” is recorded on the test sequence table and the test pattern table generated at step S1505. Furthermore, the test sequence ID of the test sequence table generated at step S1505 is recorded.

Then, it is decided whether j is j=J-1 (step S1508). When j does not satisfy j=J-1 (step S1508: No), j is incremented (step S1509), and then the procedure goes to step S1502. On the other hand, when j satisfies j=J-1 (step S1508: Yes), the test-sequence-table and test-pattern-table generating process ends.

Next, a procedure when the test sequence ID is not NULL (step S1504: No) is described by using FIG. 18. When the test sequence ID is not NULL (step S1504: No), it is decided whether the node ID on the propagation routes in the node information table extracted at step S1503 is NULL (step S1801).

When the node ID on the propagation routes is NULL (step S1801: Yes), the procedure goes to step S1505 shown in FIG. 15. On the other hand, when the node ID on the propagation routes is not NULL (step S1801: No), the node information table with the node ID on the propagation routes is extracted from the node-information-table storage unit 302 (step S1802).

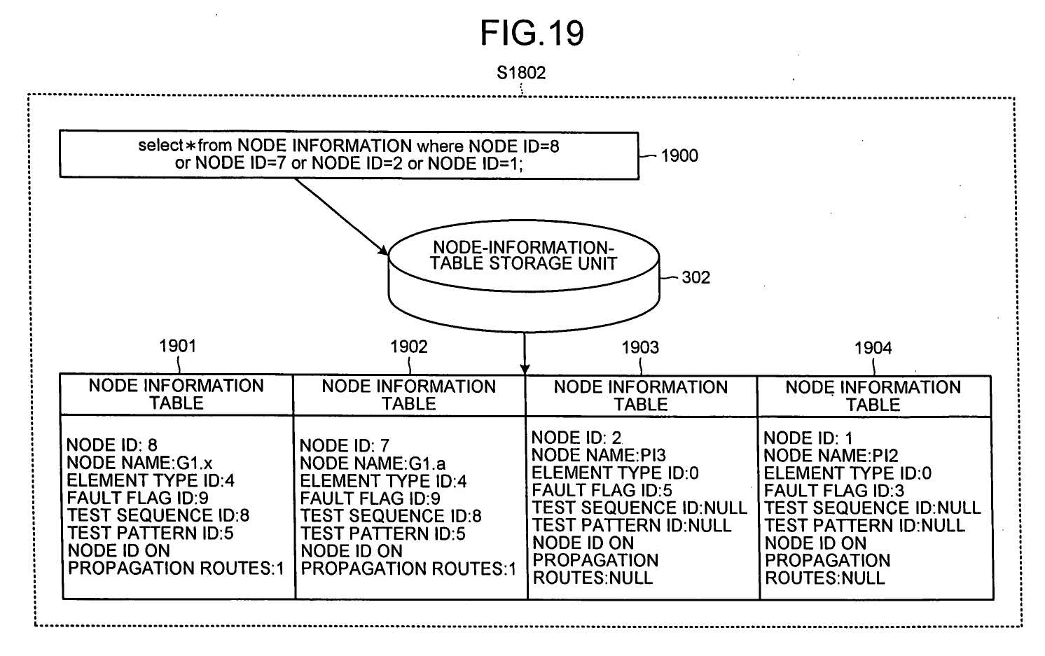

FIG. 19 is a drawing for explaining an example of extraction at step S1802 of a node information table with the node ID on propagation routes. In FIG. 19, an SQL syntax 1900 is used to extract, from the node-information-table storage unit 302, node information tables 1901 to 1904 specified by node IDs (ID=8, 7, 2, 1) on the propagation routes recorded on the node information table 1701 shown in FIG. 17.

Then, in FIG. 18, it is decided whether all test sequence IDs of the node information tables extracted at step S1802 are NULL (step S1803). When all of them are NULL (step S1803: Yes), the procedure goes to step S1505 shown in FIG. 15. On the other hand, when not all test sequence IDs of the node information tables extracted at step S1802 are NULL (step S1803: No), a test sequence table specified by the sequence ID is extracted from the test-sequence-table storage unit 305 (step S1804).

In an example shown in FIG. 19 described above, the node information table 1901 with its node ID: 8 and the node information table 1902 with its node ID: 7 have recorded thereon a test sequence ID: 8. Therefore, a test sequence tables specified by the test sequence ID: 8 is extracted from the test-sequence-table storage unit 305.

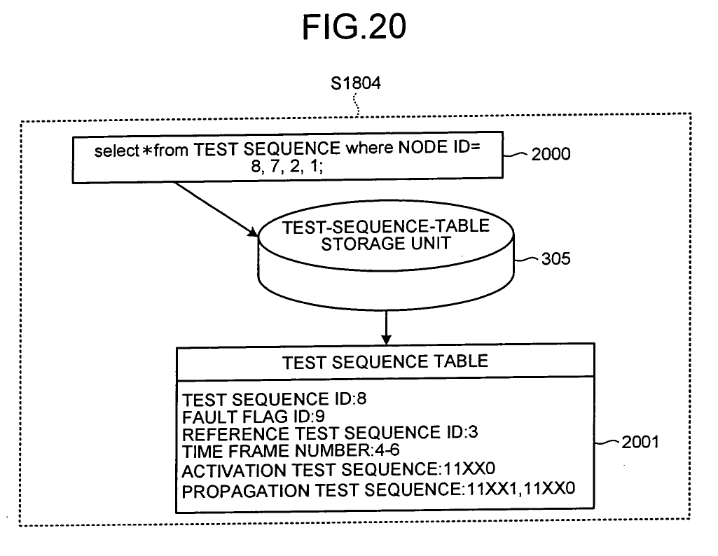

FIG. 20 is a drawing for explaining an example of extraction at step S1804 of a test sequence table. In FIG. 20, an SQL syntax 2000 is used to extract, from the test sequence table storage unit 305, a test sequence table 2001 specified by the test sequence ID: 8 recorded on the node information table 1901 shown in FIG. 19. In this case, the fault flag ID with its node ID: 8 is identical to the flag ID with its node ID: 7, and therefore they represent an equivalent fault. Therefore, one test sequence table is extracted.

Then, in FIG. 18, the number of test sequence tables extracted at step S1804 is taken as K, and an initial value of a count value k is set as k=1 (step S1805). By using a k-th extracted test sequence table, new test sequence table and test pattern table are generated (step S1806).

For example, as for the test sequence table 2001 extracted in FIG. 20 described above, in the generated test sequence, only the input signal PI has an influence on the operation of the element G1 shown in FIG. 4, and the input signals PI2 and PI3 have an influence on the operation of the element G5.x. Therefore, a test sequence with the signal values of the PI2 and PI3 being masked with X is processed through the ATPG. Then, a test sequence for activating or propagating a fault in the element G5.x is generated with expected values being set therein, and is registered as a test pattern. Also, in the generated test sequence table, the ID of the used test sequence is recorded as a reference test sequence ID.

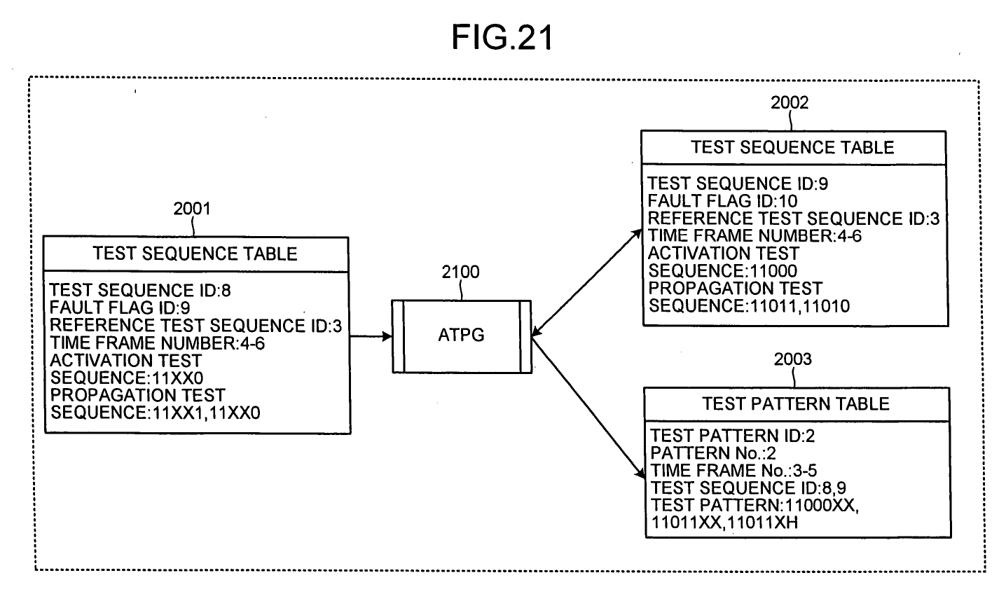

FIG. 21 is a drawing for explaining an example of an ATPG process to be performed by using the test sequence table extracted as shown in FIG. 20. In FIG. 21, an activation test sequence: 11XX0 with its test sequence ID: 8 recorded on the test sequence table 2001 is input to an ATPG 2100 to generate an activation test sequence: 11000.

Also, a propagation test sequence: 11XX1 with its test sequence ID: 8 is input to the ATPG 2100 to generate a propagation test sequence: 11011 with its test sequence ID: 9. Furthermore, a propagation test sequence: 11XX0 with its test sequence ID: 8 is input to the ATPG 2100 to generate a propagation test sequence: 11010 with its test sequence ID: 9. With this, a test sequence table 2002 with its test sequence ID: 9 is generated.

Also, an activation test sequence: 11000 with its test sequence ID: 9, a propagation test sequence: 11011, and a propagation test sequence: 11010 are input to the ATPG 2100 to generate test patterns 11000XX, 11011XX, and 11011XH. With this, a test pattern table 2003 with its test pattern ID: 2 is generated.

Then, in FIG. 18, it is decided whether k=K (step S1807). When k is not K (step S1807: No), k is incremented (step S1808), and then the procedure goes to step S1803. On the other hand, when k=K (step S1807: Yes), the procedure goes to step S1506 shown in FIG. 15.

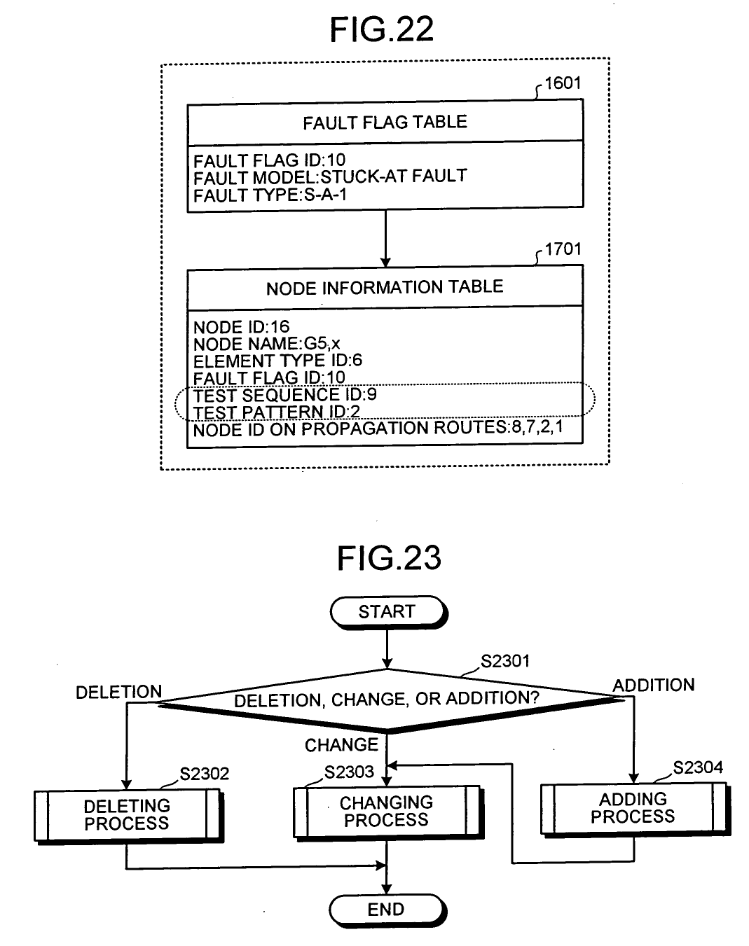

Then, table association at step S1507 shown in FIG. 15 is performed. FIG. 22 is a drawing for explaining association of a node information table with a test sequence table and a test pattern table. In FIG. 22, the test sequence table and the test pattern table generated through the procedure shown in FIG. 18 are associated with the node information table 1701 extracted at step S1503.

That is, the test sequence ID: 9 of the test sequence table 2002 and the test pattern ID: 2 of the test pattern table 2003 generated in FIG. 21 are recorded on the test sequence ID and the test pattern ID of the node information table 1701 having recorded thereon the fault flag ID: 10, respectively.

Next, a procedure of a database updating process according to the embodiment of the present invention is described. FIG. 23 is a flowchart of the procedure of the database updating process according to the embodiment of the present invention. In FIG. 23, an instruction input indicative of either one of deletion, change, and addition regarding an element included in the target circuit is provided (step S2301).

When the instruction input indicates deletion (step S2301: deletion), a deleting process is performed (step S2302). When the instruction input indicates change (step S2301: change), a changing process is performed (step S2303). When the instruction input indicates addition (step S2301: addition), an adding process is performed (step S2304).

(Procedure of the Deleting Process)

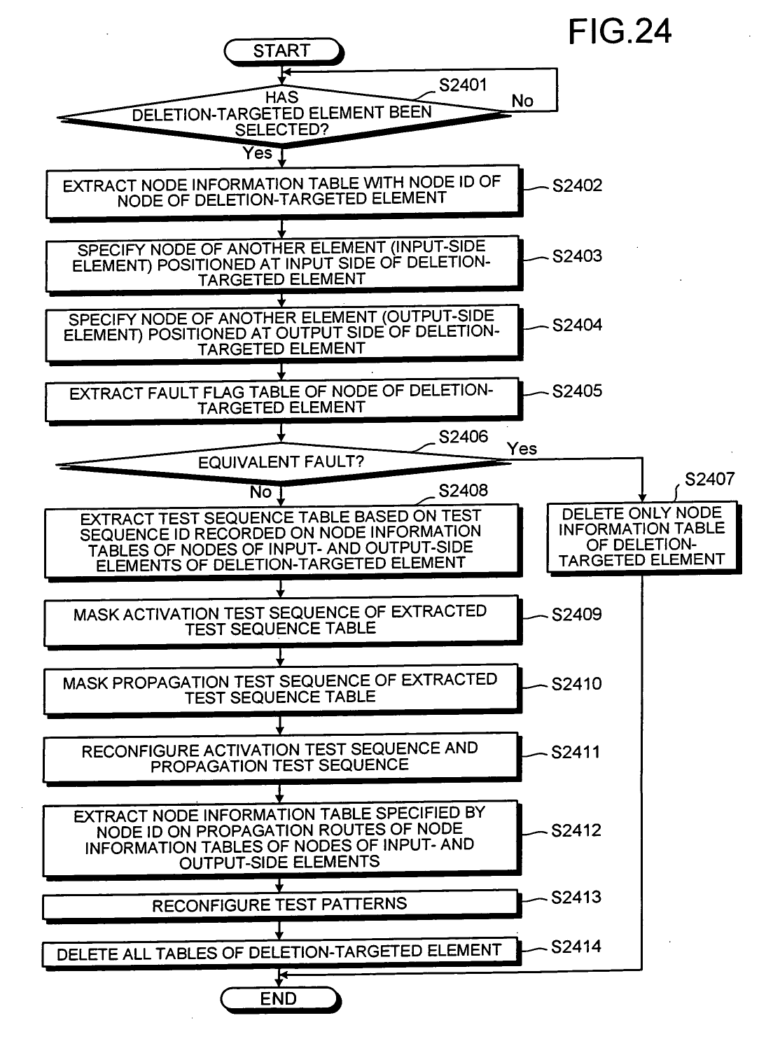

Next, a specific procedure of the deleting process shown in FIG. 23 is described. FIG. 24 is a flowchart of the specific procedure of the deleting process shown in FIG. 23. In FIG. 24, if an element to be deleted (deletion-targeted element) has been selected from among the elements in the target circuit (step S2401: Yes), a node information table having recorded therein the node ID of a node included in the selected deletion-targeted element is extracted from the node-information-table storage unit 302 (step S2402).

Then, a node of another element located at the input side of the deletion-targeted element is specified (step S2403). Specifically, a node information table specified by the node ID on the propagation routes of the node information table extracted at step S2402 is extracted from the node-information-table storage unit 302.

Also, a node of another element located at the output side of the deletion-targeted element is specified (step S2404). Specifically, a node information table, on which the node ID of the node information table extracted at step S2402 is recorded on the node ID on the propagation routes, is extracted from the node-information-table-storage unit 302.

Next, a fault flag table of the node of the deletion-targeted element is extracted (step S2405). Specifically, a fault flag table specified by the fault flag ID of the node information table extracted at step S2402 is extracted from the fault-flag-table storage unit 304. Then, it is decided whether an equivalent fault is present (step S2406). That is, it is decided whether the fault flag tables of the nodes at the input- and output-side elements include a fault flag table including an equivalent fault that is equivalent to a fault included in the fault flag table of the node of the deletion-targeted element.

When it is decided that an equivalent fault is present (step S2406: Yes), neither of the faults at the input and output sides of the deletion-targeted element has an influenced on another element. Therefore, the fault flag table, the test sequence table, and the test pattern table can be used as they are. Thus, only the node information table of the deletion-targeted element is deleted (step S2407).

On the other hand, when it is decided that no equivalent fault is present (step S2406: No), a test sequence table with the test sequence ID recorded on the node information tables (all node information tables specified at steps S2403 and S2404) of the nodes of the other elements located at the input and output sides of the deletion-targeted element is extracted from the test-sequence-table storage unit 305 (step S2408).

Then, an input terminal serving as a signal propagation source to the deletion-targeted element is specified. In the activation test sequence recorded on the test sequence table extracted at step S2408, a value to be input to the specified input terminal is masked to “X” (step S2409).

Similarly, an input terminal serving as a signal propagation source to the deletion-targeted element is specified. In the propagation test sequence recorded on the test sequence table extracted at step S2408, a value to be input to the specified input terminal is masked to “X” (step S2410).

Then, a test sequence table specified by the reference test sequence ID recorded on the test sequence table extracted at step S2408 is extracted from the test-sequence-table storage unit 305. By using the test sequence recorded on the extracted test sequence table, the masked activation test sequence, and the masked propagation test sequence, the activation test sequence and the propagation test sequence are reconfigured through the ATPG (step S2411).

Then, a node information table specified by the node ID on the propagation routes in the node information tables (all node information tables specified at steps S2403 and S2404) of the nodes of the other elements positioned at input and output sides of the deletion-targeted element is extracted from the node-information-table storage unit 302 (step S2412).

By using the activation test sequence and the propagation test sequence reconfigured at step S2411, the test sequence table specified by the test sequence ID of the node information table extracted at step S2412 is extracted from the test-sequence-table storage unit 305. Then, the propagation test sequence recorded on the extracted test sequence table is reconfigured through the ATPG.

Here, the test sequence table and the test pattern table are associated with each other. Therefore, with the reconfiguration of the propagation test sequence, the test patterns on the test pattern table associated with the test sequence table in which the reconfigured propagation test sequence is recorded are also reconfigured through the ATPG (step S2413).

Then, all tables for the deletion-targeted element (the test sequence table, the test pattern table, the fault flag table, and the node information table) are deleted (step S2414). With this, updating when an element in the target circuit is deleted can be automatically performed.

(First Example of Deletion)

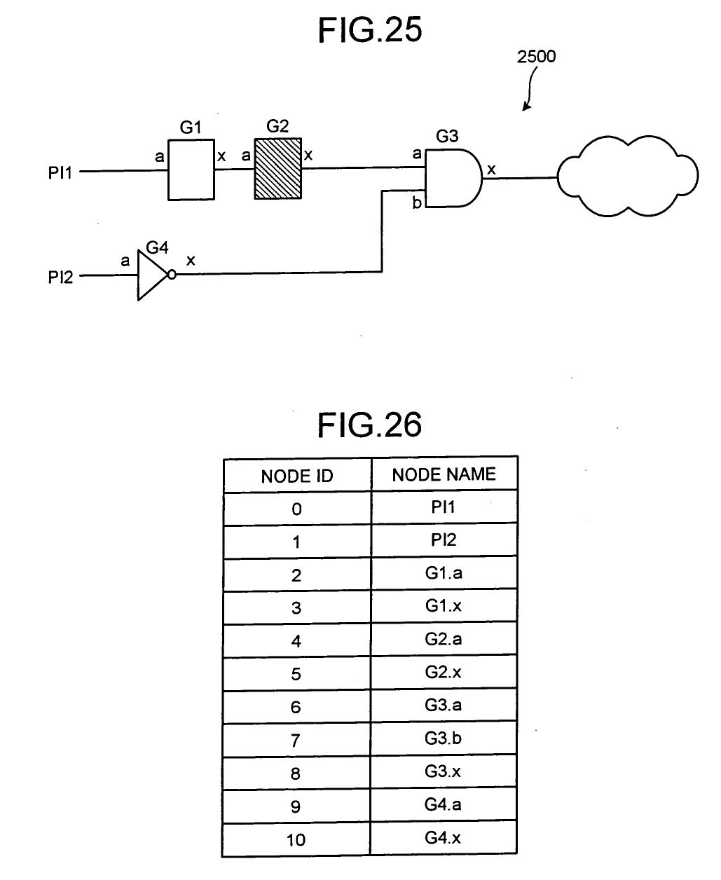

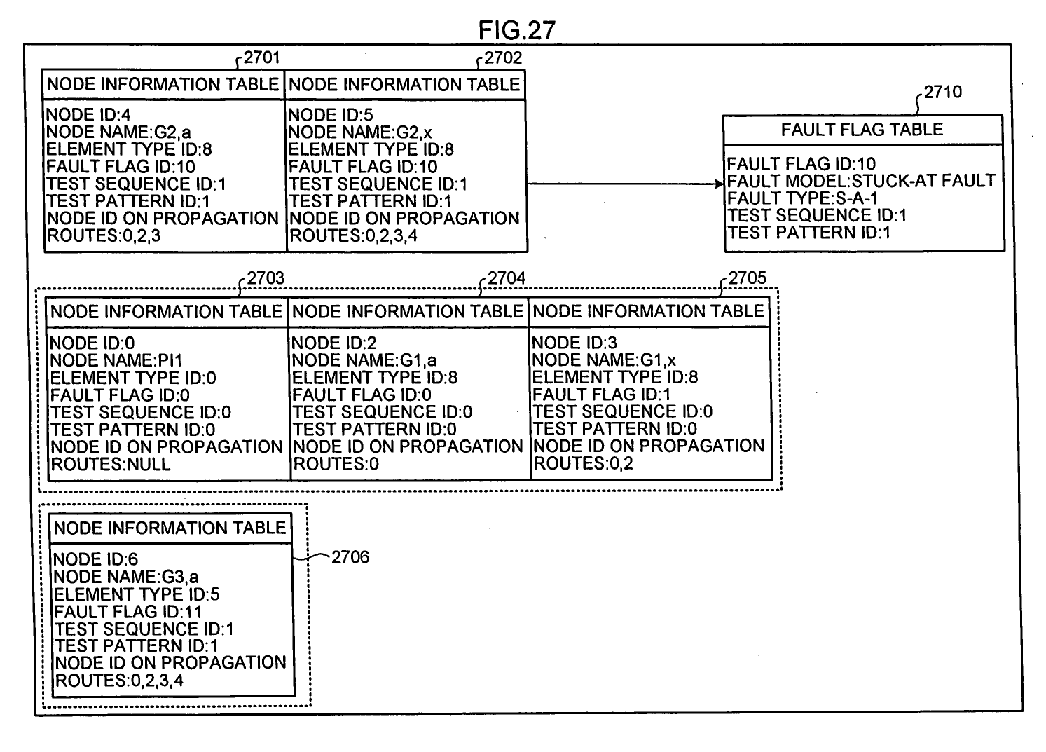

Next, a first specific example of the process of deleting an element in the target circuit described above is described. FIG. 25 is a block diagram of one example of the target circuit. FIG. 26 is a table of a correspondence between node names and node IDs for the target circuit shown in FIG. 25. FIG. 27 is a schematic drawing that depicts a process of deleting an element in the target circuit shown in FIG. 25.

In a target circuit 2500, when an element G2 shown in FIG. 25 is taken as the deletion-targeted element, node information tables 2701 and 2702 with the node IDs: 4 and 5 shown in FIG. 27 are extracted at step S2402 shown in FIG. 24. Also, since other elements at input side of the deletion-targeted element G2 (input-side elements) are an input terminal PI1 and an element G1. Therefore, node information tables 2703 to 2705 with the node IDs on the propagation routes: 0, 2, and 3 of the node information tables with the node IDs: 4 and 5 are extracted at step S2403 shown in FIG. 24. Therefore, as the nodes at the input-side elements of the deletion-targeted element G2, the node PI1, a node G1.a, and a node G1.x can be specified.

Similarly, another element at the output side of the deletion-targeted element G2 (output-side element) is an AND circuit G3. Therefore, node information tables, such as a node information table 2706 with its node ID: 6, recorded with their node IDs: 4 and 5 of the node information table of the deletion-targeted element G2 being recorded as the node IDs on the propagation routes are extracted at step S2404 shown in FIG. 24.

Also, a fault flag table 2710 with its fault flag ID: 10 recorded on the node information tables with their node IDs: 4 and 5 is extracted at step S2405 shown in FIG. 24. Also, it is decided as to equivalent fault decision at step S2406 that an equivalent fault is present, only the node information table with its node IDs: 4 and 5 of the node of the deletion-targeted element is deleted at step S2407.

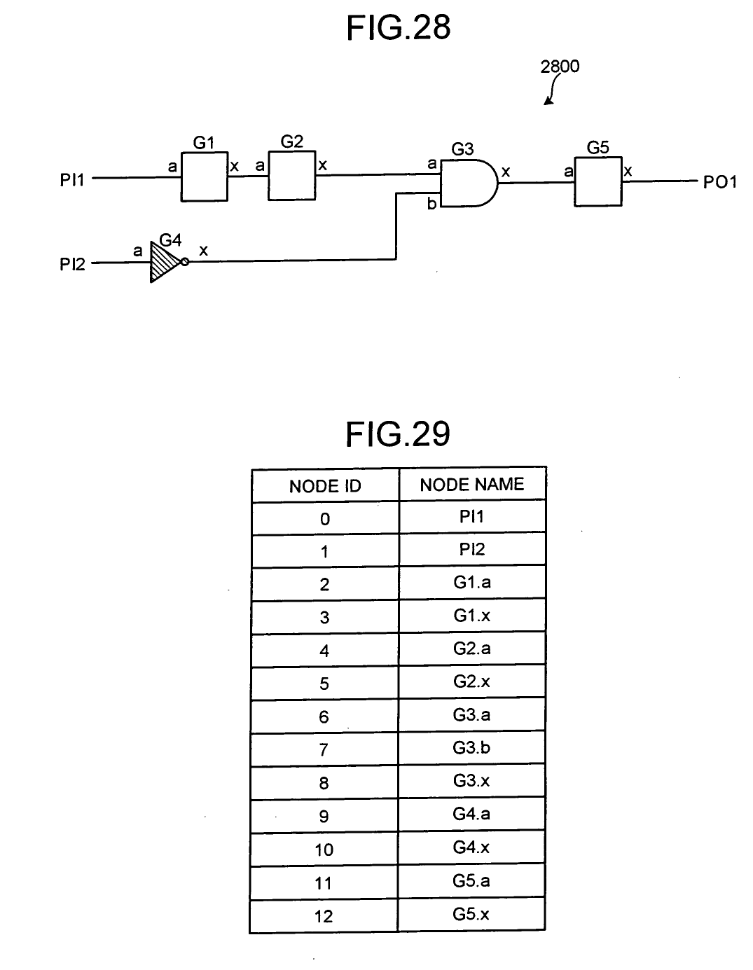

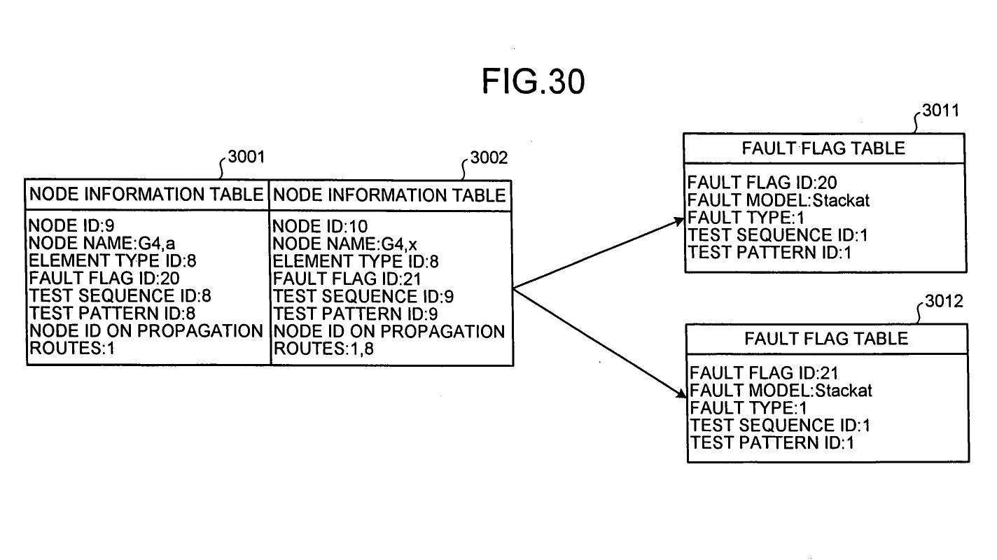

Next, a second specific example of the process of deleting an element in the target circuit described above is described. FIG. 28 is a block diagram of one example of the target circuit. FIG. 29 is a table of a correspondence between node names and node IDs for the target circuit shown in FIG. 28. FIGS. 30 to 32 are schematic drawings that depict a process of deleting an element in the target circuit shown in FIG. 28.

In a target circuit 2800, when an inverter element G4 shown in FIG. 28 is taken as the deletion-targeted element, node information tables 3001 and 3002 with the node IDs: 9 and 10 shown in FIG. 30 are extracted at step S2402 shown in FIG. 24.

Also, since another element at input side of the deletion-targeted element G4 (input-side element) is an input terminal P12. Therefore, a node information table 3101 with the node ID on the propagation routes: 1 recorded on the node information tables 3001 and 3002 with the node IDs: 9 and 10 are extracted at step S2403 shown in FIG. 24. Therefore, as the node at the input-side elements of the deletion-targeted element G4, the node PI2 can be specified.

Similarly, other elements at the output side of the deletion-targeted element G4 (output-side elements) are an AND circuit G3 and an element G5. Therefore, node information tables, such as a node information table 3202 with its node ID: 7, recorded with their node IDs: 9 and 10 of the node information table of the deletion-targeted element G4 being recorded as the node IDs on the propagation routes are extracted at step S2404 shown in FIG. 24.

Also, in FIG. 30, fault flag tables 3011 and 3012 with their fault flag IDs: 20 and 21 recorded on the node information tables with their node IDs: 9 and 10 are extracted at step S2405 shown in FIG. 24.

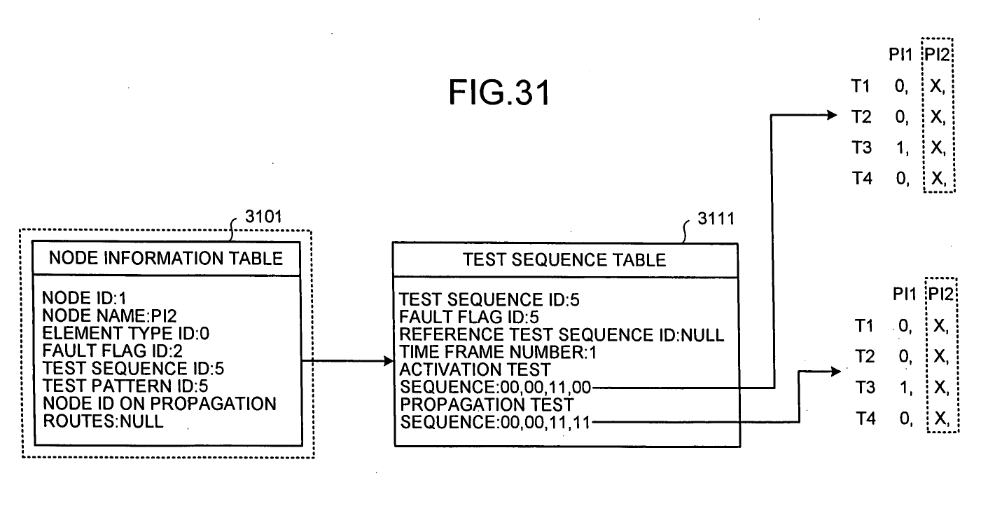

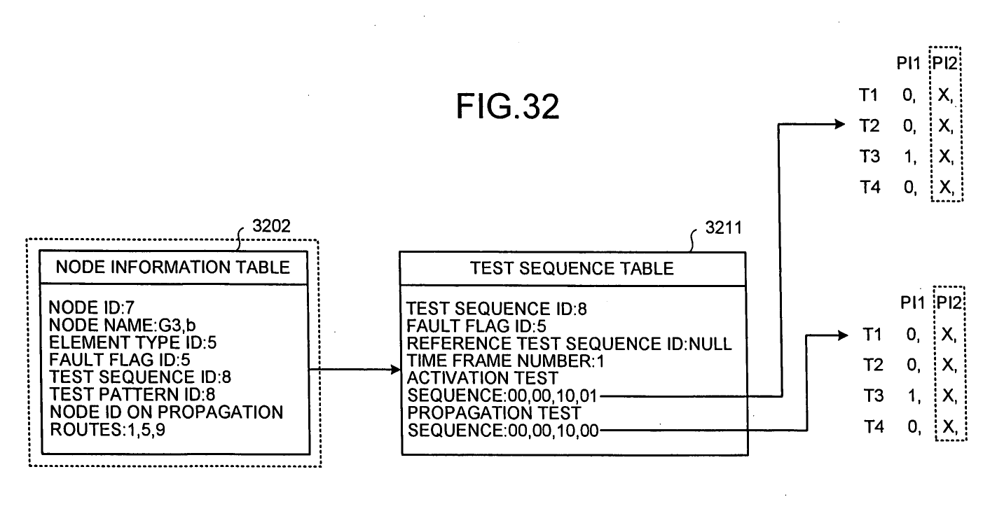

Also, it is decided as to equivalent fault decision at step S2406 that no equivalent fault is present, a test sequence table 3111 with its test sequence ID: 5 recorded on the node information table with the node ID: 1 shown in FIG. 31 is extracted at step S2408 shown in FIG. 24. Similarly, a test sequence table 3211 with its test sequence ID: 8 recorded on the node information table with the node ID: 7 shown in FIG. 32 is extracted at step S2409 shown in FIG. 24.

At step S2409 shown in FIG. 24, an input terminal PI2 is specified as a signal propagation source to the deletion-targeted element G4. In the activation test sequence and the propagation test sequence recorded on the test sequence table shown in FIG. 31, a value to be input to the input terminal PI2 is masked to “X” (either one of 1 and 0).

Similarly, at step S2409 shown in FIG. 24, the input terminal P12 is specified as a signal propagation source to the deletion-targeted element G4. In the activation test sequence and the propagation test sequence recorded on the test sequence table shown in FIG. 32, a value to be input to the input terminal PI2 is masked to “X”.

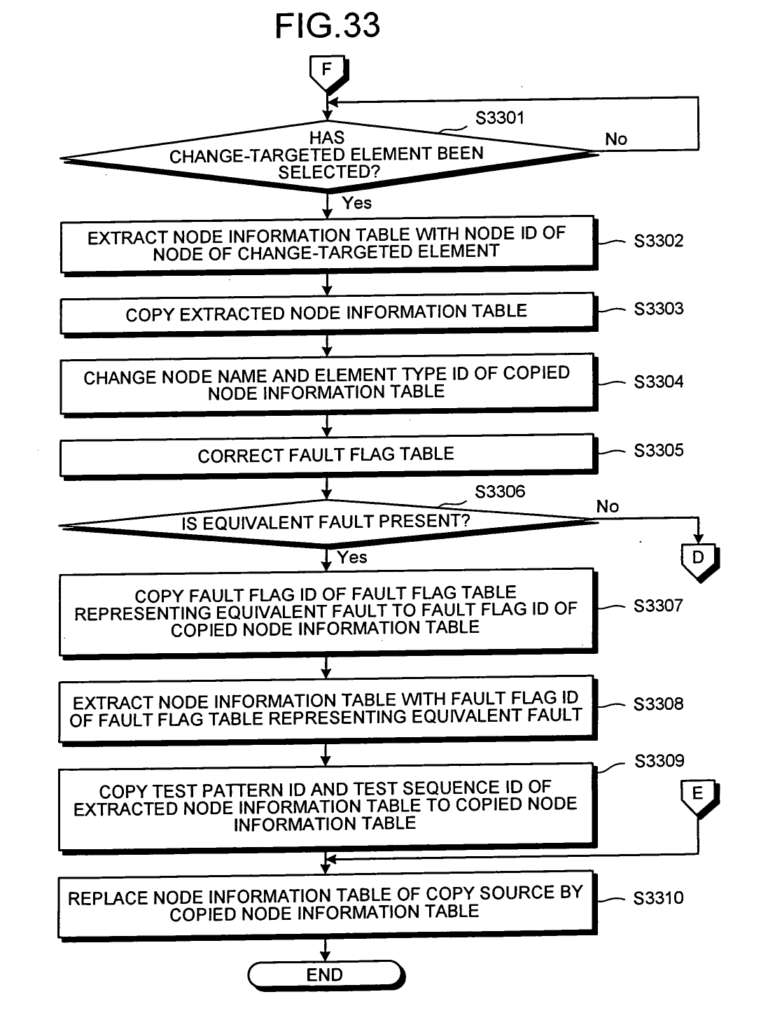

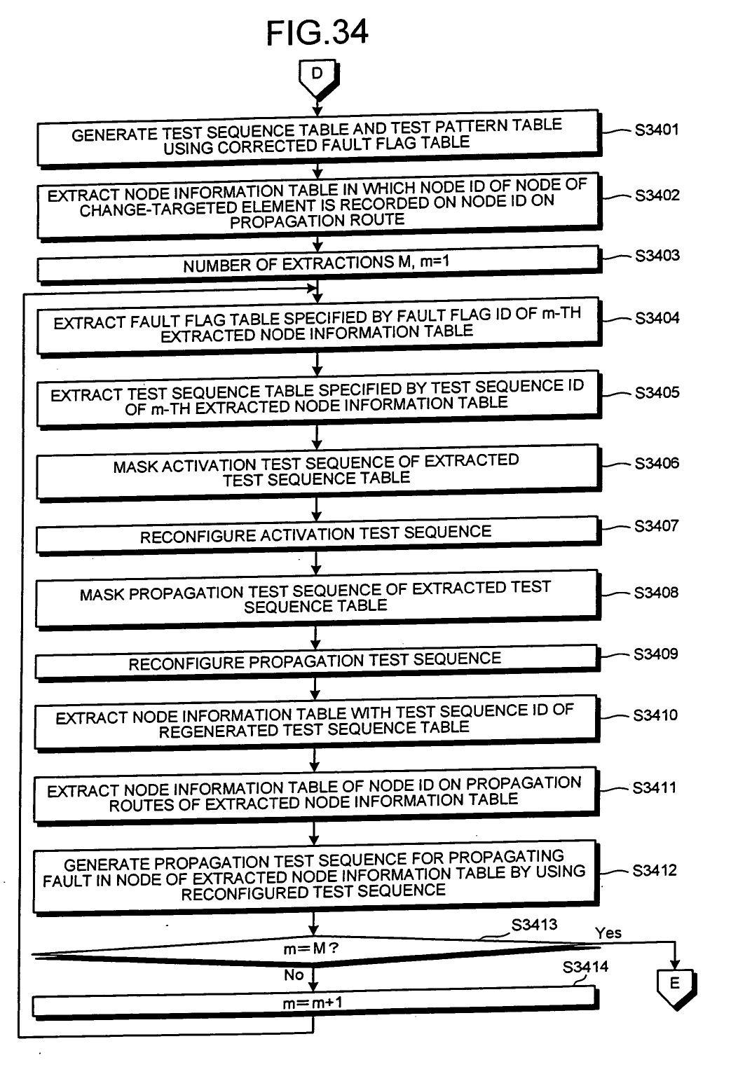

Next, a specific procedure of the changing process shown in FIG. 23 is described. FIGS. 33 and 34 are flowcharts of the specific procedure of the changing process shown in FIG. 23. In FIG. 33, if an element to be changed (change-targeted element) has been selected from among the elements in the target circuit, (step S3301: Yes), a node information table having recorded therein the node ID of the node included in the selected change-targeted element is extracted from the node-information-table storage unit 302 (step S3302).

Then, the node information table extracted at step S3302 is copied to the work area (step S3303). This can prevent consistency among the databases from being destroyed due to the influence of the element change during the changing process. Next, the node name and the element type ID of the copied node information table are changed (step S3304). Also, with the fault flag ID of the copied node information table, a fault flag table is extracted, and then the fault flag table is corrected (step S3305).

Then, by using the corrected fault flag table, an equivalent fault is searched for (step S3306). The case in which no equivalent fault is present (step S3306: No) will be described further below, in FIG. 34. On the other hand, when an equivalent fault is present (step S3306: Yes), a fault flag ID of the fault flag table including the equivalent fault is copied to the fault flag ID of the node information table copied at step S3303 (step S3307).

Then, a node information table having the fault flag ID of the fault flag table including the equivalent fault is extracted from the node-information-table storage unit 302 (step S3308). Then, the test pattern ID and the test sequence ID of the node information table extracted at step S3308 are copied to the copied node information table (step S3309). Finally, the node information table of the copy source (change source) is replaced by the copied node information table (step S3310).

When no equivalent fault is present at step S3306 (step S3306: No), in FIG. 34, the corrected fault flag table is used to generate a test sequence table and a test pattern table (step S3401). Specifically, a scheme similar to the test-sequence-table and test-pattern-table generating process shown in FIG. 11 (step S1104) is used for generation.

Next, of the node information tables stored in the node-information-table storage unit 302, a node information table on which the node ID of the node of the change-targeted element is recorded on the node ID on the propagation routes is extracted (step S3402). Then, the number of extractions is taken as M, and its initial value M is set as m=1 (step S3403).

Then, a fault flag table specified by a fault flag ID of an m-th extracted node information table is extracted (step S3404). Also, a test sequence table specified by a test sequence ID of the m-th extracted node information table is extracted (step S3405).

Then, an input terminal serving as a signal propagation source to the change-targeted element is specified. In the activation test sequences recorded on the test sequence table extracted at step S3405, a value to be input to the specified input terminal is masked to “X” (step S3406). This masked activation test sequence is used to reconfigure the activation test sequence through ATPG (step S3407).

Similarly, an input terminal serving as a signal propagation source to the change-targeted element is specified. In the propagation test sequence recorded on the test sequence table extracted at step S3405, a value to be input to the specified input terminal is masked to “X” (step S3408). This masked propagation sequence is used to reconfigure the propagation sequence through ATPG (step S3409).

A node information table having the test sequence ID of the reconfigured test sequence tables including these reconfigured active test sequence and propagation test sequence is then extracted (step S3410). A node information table with the node ID on the propagation route of the node information table extracted at step S3410 is then extracted (step S3411).

The test sequences reconfigured at steps S3407 and S3409 are used to generate a propagation test sequence for propagating the fault in the node of the node information node table extracted at step S3411 (step S3412). Then, when m is not M (step S3413: No), m is incremented (step S3414), and the procedure then goes to step S3404. On the other hand, when m=M (step S3143: Yes), the procedure then goes to step S3310 shown in FIG. 33.

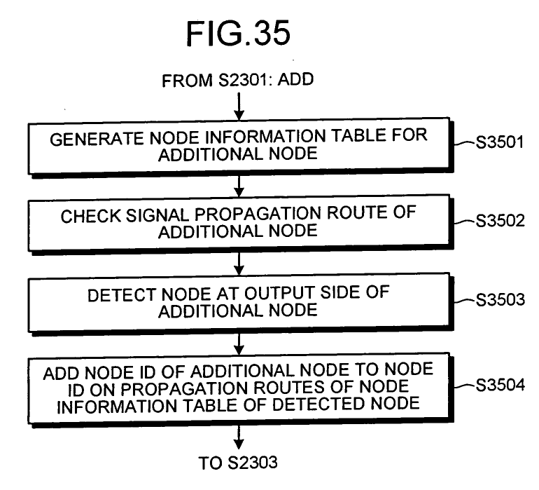

Next, a specific procedure of the adding process shown in FIG. 23 is described. FIG. 35 is a flowchart of the specific procedure of the adding process shown in FIG. 23. In FIG. 35, firstly, a node information table of an additional node is generated (step S3501). Next, a signal propagation route for the additional node is checked (step S3502). With this check, a node at the output side of the additional node is detected (step S3503). Then, the node ID of the additional node is added to the node ID on the propagation routes of the node information table of this detected node (step S3504). The procedure then goes to step S2303.

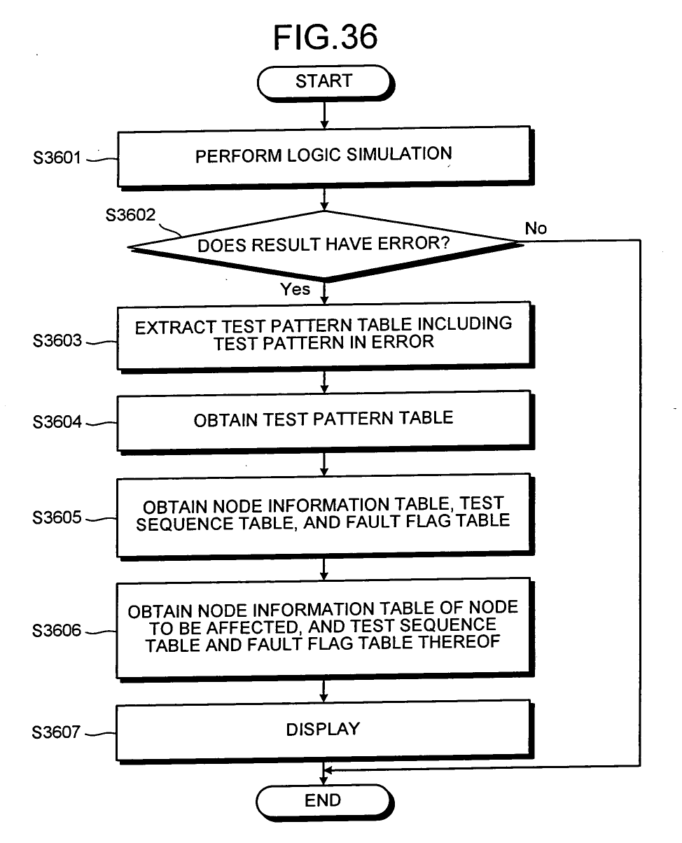

Next, a test pattern analyzing process of the test pattern generation and analysis device according to one embodiment of the present invention is described. FIG. 36 is a flowchart of a procedure of the test pattern analyzing process of the test pattern generation and analysis device according to the embodiment of the present invention.

In FIG. 36, inputs are provided to a logic simulator for the generated test patterns to perform a logic simulation for the target circuit (step S3601). It is then decided whether the simulation result has an error (step S3602). When no error is present (step S3602: No), outputs according to expected values have been obtained, thereby ensuring the operation of the target circuit. The procedure then ends.

On the other hand, when the simulation result has an error (step S3602: Yes), a test pattern table including a test pattern in error is extracted (step S3603). Also, the node information table, the test sequence table, and the fault flag table having recorded thereon the test pattern ID of the extracted test pattern table are obtained (step S3604).

Also, the node information table specified by the node ID on the propagation routes of the node information table extracted at step S3604, the test sequence table specified by the test sequence ID of the node information table, and the fault flag table specified by the fault flag ID of the node information table are obtained (step S3605).

Furthermore, the node information table having recorded on the node ID on the propagation routes the node ID of the node information table obtained at step S3604, the test sequence table specified by the test sequence ID of the node information table, and the fault flag table specified by the fault flag ID of the node information table are obtained (step S3606).

Then, the tables obtained at steps S3603 to S3606 are used to analyze the details of the error occurred at step S3602 through an analysis tool for display on a display screen (step S3607). With these tables being used for error analysis, the cause of the error can be easily specified, thereby reducing the time of analyzing the result.

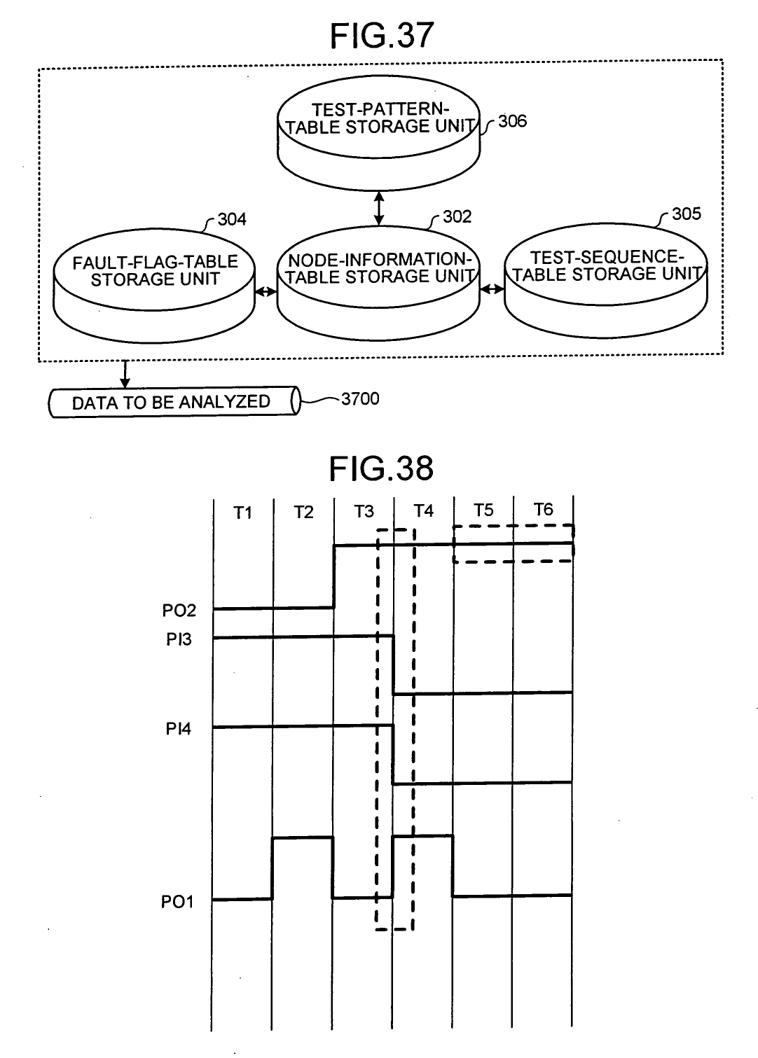

Next, the test pattern analyzing process shown in FIG. 36 is specifically described. FIG. 37 is a schematic diagram of the test pattern analyzing process shown in FIG. 36. In FIG. 37, the test pattern table 306 is searched for a test pattern table coinciding with the pattern number of the pattern table in error at the logical simulation. The node-information-table storage unit 302 is searched for a node information table of the node ID associated with the test pattern table. The fault-flag-table storage unit 304 is searched for a fault flag table associated therewith. The test-sequence-table storage unit 305 is searched for a test sequence table associated therewith. These tables are searched for as information required for error analysis (data to be analyzed 3700).

Although difference conditions are required for analysis depending on the conditions of the error, the position of the element where the error occurred, the node information table of the node having an influence on the operation of that element, and the test sequence table can be known. Based on the information on these tables, the cause of the error can be specified by using the existing waveform analysis tool or circuit diagram display tool. Specifically, with the analysis tool, a simulation is performed according to the error based on the information on these tables and the details of the error to specify the cause. For example, to specify the cause of a timing error, a simulation is again performed as to signal propagation between the node in error and the associated nodes, and then a portion of waveforms that is different from those expected by the ATPG is displayed.

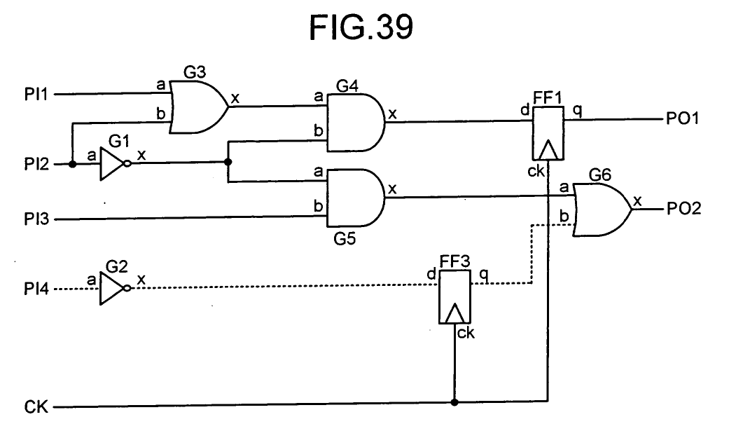

FIG. 38 is a drawing of waveforms obtained through a waveform analysis tool. FIG. 38 depicts a state in which the value of the input signal PI4 is not captured by the FF because a set-up time is short during time frames T3 and T4, but expected values of the output signal P02 are different during time frames T5 and T6, thereby causing an error. FIG. 39 is a circuit diagram displayed by a circuit diagram displaying tool. FIG. 39 depicts a state in which an error occurs on a propagation route denoted by a dotted line.

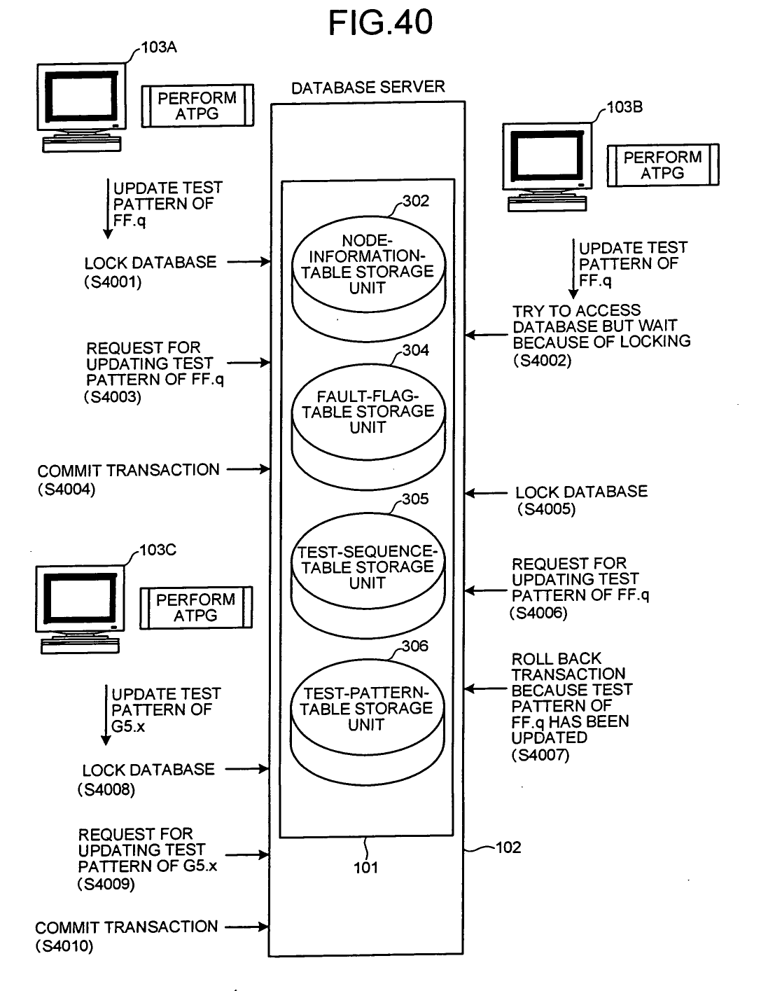

Next, a transaction process in the test pattern generation and analysis system 100 according to the embodiment of the present invention is described. FIG. 40 is a drawing for explaining the transaction process in the test pattern generation and analysis system 100 according to one embodiment of the present invention.

First, it is assumed that the work station 130A updates a test pattern of FF.q and reflects the update on the database. At this time, the database 101 locks the database 101 (step S4001) to prevent the other work stations 103B and 103C from update the database 101.

The work station 103B issues a request for updating the test pattern of FF.q to the database server 102, but waits for an updating process because the database 101 is locked (step S4002). Also, a process (update request) for updating the test pattern of FF.q is transmitted from the work station 103A to the database 101 (step S4003) to COMMIT (reflect) a transaction (step S4004).

Upon completion of this COMMIT, the locked database 101 is released simultaneously. Then, the work station 103B locks the database 101 (step S4005) to issue a request for updating the test pattern of FF.q (step S4006). However, since the process on FF.q contradicts the process of the work station 103A, the transaction is ROLLED BACK, and then the details of the update request are discarded (step S4007).

On the other hand, the work station 103C performs a process of reflecting the process result of another element G5.x, that is, locks the database 101 (steps S4008 to S4010). In this process, the other work stations 103A and 103B do not use the database 101, the process result is directly reflected on the database. With such a process, a plurality of work stations 103A to 103C can simultaneously perform an ATPG process on the same design data.

As such, according to the embodiment of the present invention described above, when a test pattern of a target fault is generated through the ATPG, the relevant fault flag table, node information table, test sequence table already detected can be extracted based on the fault flag.

Also, with the use of these pieces of table information, seed values required for test pattern generation can be set, and also a recyclable test sequence can be extracted, thereby reducing the processing time of the ATPG and the number of test patterns. Furthermore, a redundant circuit, which is problematic in ATPG processing, is detected based on the circuitry relation, and is set as being excluded from the test, thereby reducing the redundant processing time of the ATPG.

Still further, if an element is required to be changed, only updating a necessary table is enough to update all pieces of information. This can increase the speed of test pattern generation after the element is changed. Still further, in error analysis in a logic simulation, possible causes of the error are extracted from a database, and information required for analysis can be obtained. With this, the user can narrow down the cause of the error, thereby significantly reducing time to be taken for analysis.

Still further, a transaction process is performed such that the database for use in test pattern generation is locked when updated and updating from other work stations 103 is temporarily put on hold. With this, a plurality of users can simultaneously perform processes at the plurality of work stations 103. This can increase the processing speed of the ATPG through parallel processing. Also, if a failure occurs in a system on hardware, a roll-back process is performed to recover the already-detected information and resume the processing in a short period of time.

Still further, a database access function in CAD development is made operable with a general SQL. With this, the interface among manufactures can be unified. Also, the user can select and use various kinds of ATPGs, fault analysis tools, and logic simulations.

That is, the database 101 (the net list storage unit 301, the node-information-table storage unit 302, the element-type-ID storage unit 303, the fault-flag-table storage unit 304, the test-sequence-table storage unit 305, and the test-pattern-table storage unit 306) may be operable with a database access function, such as the SQL, to increase a process of accessing various data described above for improving the processing speed of the ATPG, thereby making it easier to develop an analysis tool. Also, with a unified database language, an analysis tool created by another CAD manufacturer can be used.

As has been described in the foregoing, according to the test-pattern generation system, the test-pattern analysis system, the test-pattern generation method, the test-pattern analysis method, the test-pattern generation program, the test-pattern analysis program, and the recording medium therefor, effects of reducing an ATPG processing time and the number of redundant test patterns can be achieved.

The test-pattern generation method and the test-pattern analysis method described in the present embodiment can be achieved by executing a program provided in advance on a computer, such as a personal computer or the work stations 103. This program is recorded on a computer-readable recording medium, such as a CD-ROM, MO, or DVD, and is executed by being read by the computer from the recording medium. Also, the program may be a transmission medium that can be distributed via the network 104, such as the Internet.

According to the present invention, it is possible to reduce an ATPG processing time and the number of redundant test patterns.

Although the invention has been described with respect to a specific embodiment for a complete and clear disclosure, the appended claims are not to be thus limited but are to be construed as embodying all modifications and alternative constructions that may occur to one skilled in the art which fairly fall within the basic teaching herein set forth.

What is claimed is:

1. A test-pattern generation system comprising:
a net-list input unit that inputs a net list of a circuit;
a first terminal-information generating unit that generates, for each terminal included in elements that form the circuit, first terminal information that includes identification information of one of the terminal and propagation route information that indicates identification information of another of the terminal that is located on a signal propagation route to one of the terminal based on the net list;
a first fault-detection-information generating unit that generates first-fault detection information for detecting a fault in the terminal for each of the first terminal information generated;
a test-sequence-information determining unit that determines whether the first fault-detection information includes identification information of a test sequence;
a test-sequence generating unit that generates the test sequence for the first fault-detection information that is determined that the first fault-detection information includes the identification information of the test sequence by the test-sequence-information determining unit; and
a test-pattern generating unit that generates a test pattern using the test sequence generated.

2. The test-pattern generation system according to claim 1, further comprising:
a propagation-route-information determining unit that determines whether the first terminal information that includes the first fault-detection information that is determined that the fist fault-detection information does not include the identification information of the test sequence includes the propagation route information;
a terminal-information extracting unit that extracts, when the propagation-route-information determining unit determines that the fist terminal information includes the propagation route information, the first terminal information specified by the propagation route information from among the first terminal information generated;
a second test-sequence-information determining unit that determines whether the first terminal information extracted includes the identification information of the test sequence; and
a test-sequence-information extracting unit that extracts the identification information of the test sequence from the first terminal information extracted based on a result of determination by the second test-sequence-information determining unit, wherein
the test-sequence generating unit generates a second test sequence using the test sequence specified by the identification information of the test sequence extracted when the test-sequence-information determining unit determines that the first fault-detection information includes the identification information of the test sequence, and
the test-pattern generating unit generates a second test pattern using the second test sequence.

3. The test-pattern generation system according to claim 1, further comprising:
a selecting unit that selects an element from among the elements in the circuit;
a first fault-detection-information extracting unit that extracts, from among the first fault-detection information generated, first fault-detection information that is specified by the first terminal information of the terminal included in the element selected;
a propagation-route-information detecting unit that detects propagation route information that indicates identification information of the terminal included in another of the element on a signal propagation route on which the element selected is present;
a second fault-detection-information extracting unit that extracts, from among the first fault detection information extracted, second fault-detection information for detecting a fault in the terminal specified by the propagation route information detected;
an equivalent-fault determining unit that determines whether the second fault-detection information extracted includes a fault that is equivalent to the fault included in the first fault-detection information extracted; and
a deleting unit that deletes, based on a result of determination by the equivalent-fault determining unit, the first terminal information of the terminal in the element selected.

4. The test-pattern generation system according to claim 1, further comprising:
a selecting unit that selects an element from among the elements in the circuit;
a second terminal-information generating unit that generates second terminal information that includes identification information of one of the terminal included in an element that is different from the element selected and propagation route information that indicates identification information of another of the terminal that is located on a signal propagation route to the element selected;
a second fault-detection-information generating unit that generates second fault-detection information for detecting a fault in the terminal that is specified by the second terminal information;
an equivalent-fault determining unit that determines whether the first fault-detection information includes a fault that is equivalent to the fault included in the second fault-detection information generated; and
a changing unit that changes the first terminal information of the terminal in the element selected to the second terminal information of the terminal in the element based on a result of determination by the equivalent-fault determining unit.

5. The test-pattern generation system according to claim 1, further comprising:
a position selecting unit that selects a position at which an additional element, which is an element other than the elements that form the circuit, is added;
a second terminal-information generating unit that generates second terminal information that includes identification information of the terminal included in the additional element and propagation route information that indicates identification information of another of the terminal that is located on a signal propagation route to the position selected; and
an adding unit that adds the identification information of the terminal that is specified by the second terminal information generated to the propagation route information in the first terminal information.

6. A test-pattern analysis system comprising:
a net-list input unit that inputs a net list of a circuit;
a first terminal-information generating unit that generates, for each terminal included in elements that form the circuit, first terminal information that includes identification information of one of the terminal and propagation route information that indicates identification information of another of the terminal that is located on a signal propagation route to one of the terminal based on the net list;
a first fault-detection-information generating unit that generates first-fault detection information for detecting a fault in the terminal for each of the first terminal information generated;
a test-sequence-information determining unit that determines whether the first fault-detection information includes identification information of a test sequence;
a test-sequence generating unit that generates the test sequence for the first fault-detection information that is determined that the first fault-detection information includes the identification information of the test sequence by the test-sequence-information determining unit;
a test-pattern generating unit that generates a test pattern using the test sequence generated;
a simulation performing unit that performs a logic simulation on the circuit using the test pattern generated;
an obtaining unit that obtains information that includes the test sequence with which the test pattern is generated, the first fault-detection information with which the test sequence is generated, and the fist terminal information of the terminal in which a fault is detected, when a result of the logic simulation includes an error; and
an analyzing unit that analyzes the error included in the result using the information obtained.

7. A test-pattern generation method comprising:
inputting a net list of a circuit;
generating, for each terminal included in elements that form the circuit, first terminal information that includes identification information of one of the terminal and propagation route information that indicates identification information of another of the terminal that is located on a signal propagation route to the one of the terminal based on the net list;
generating first-fault detection information for detecting a fault in the terminal for each of the first terminal information generated;
determining whether the first fault-detection information includes identification information of a test sequence;
generating the test sequence for the first fault-detection information that is determined that the first fault-detection information includes the identification information of the test sequence; and
generating a test pattern using the test sequence generated.

8. The test-pattern generation method according to claim 7, further comprising:
determining whether the first terminal information that includes the first fault-detection information that is determined that the fist fault-detection information does not include the identification information of the test sequence includes the propagation route information;
extracting, when the propagation-route-information determining unit determines that the fist terminal information includes the propagation route information, the first terminal information that is specified by the propagation route information from among the first terminal information generated;
determining whether the first terminal information extracted includes the identification information of the test sequence; and
extracting the identification information of the test sequence from the first terminal information extracted based on a result obtained at the determining;
generating a second test sequence using the test sequence specified by the identification information of the test sequence extracted when the test-sequence-information determining unit determines that the first fault-detection information includes the identification information of the test sequence; and
generating a second test pattern using the second test sequence.

9. A test-pattern analysis method comprising:
inputting a net list of a circuit;
generating, for each terminal included in elements that form the circuit, first terminal information that includes identification information of one of the terminal and propagation route information that indicates identification information of another of the terminal that is located on a signal propagation route to one of the terminal based on the net list;
generating first-fault detection information for detecting a fault in the terminal for each of the first terminal information generated;
determining whether the first fault-detection information includes identification information of a test sequence;
generating the test sequence for the first fault-detection information that is determined that the first fault-detection information includes the identification information of the test sequence;
generating a test pattern using the test sequence generated;
performing a logic simulation on the circuit using the test pattern generated;
obtaining information that includes the test sequence with which the test pattern is generated, the first fault-detection information with which the test sequence is generated, and the fist terminal information of the terminal in which a fault is detected, when a result of the logic simulation includes an error; and
analyzing the error included in the result using the information obtained.

10. A computer-readable recording medium that stores a computer program for generating a test-pattern, the computer program making a computer execute:
inputting a net list of a circuit;
generating, for each terminal included in elements that form the circuit, first terminal information that includes identification information of one of the terminal and propagation route information that indicates identification information of another of the terminal that is located on a signal propagation route to the one of the terminal based on the net list;
generating first-fault detection information for detecting a fault in the terminal for each of the first terminal information generated;
determining whether the first fault-detection information includes identification information of a test sequence;
generating the test sequence for the first fault-detection information that is determined that the first fault-detection information includes the identification information of the test sequence; and
generating a test pattern using the test sequence generated.

11. The computer-readable recording medium according to claim 10, wherein the computer program further makes the computer execute:
determining whether the first terminal information that includes the first fault-detection information that is determined that the fist fault-detection information does not include the identification information of the test sequence includes the propagation route information;
extracting, when the propagation-route-information determining unit determines that the fist terminal information includes the propagation route information, the first terminal information that is specified by the propagation route information from among the first terminal information generated;
determining whether the first terminal information extracted includes the identification information of the test sequence; and
extracting the identification information of the test sequence from the first terminal information extracted based on a result obtained at the determining;
generating a second test sequence using the test sequence specified by the identification information of the test sequence extracted when the test-sequence-information determining unit determines that the first fault-detection information includes the identification information of the test sequence; and
generating a second test pattern using the second test sequence.

12. A computer-readable recording medium that stores a computer program for analyzing a test-pattern, the computer program making a computer execute:
inputting a net list of a circuit;
generating, for each terminal included in elements that form the circuit, first terminal information that includes identification information of one of the terminal and propagation route information that indicates identification information of another of the terminal that is located on a signal propagation route to one of the terminal based on the net list;
generating first-fault detection information for detecting a fault in the terminal for each of the first terminal information generated;
determining whether the first fault-detection information includes identification information of a test sequence;
generating the test sequence for the first fault-detection information that is determined that the first fault-detection information includes the identification information of the test sequence;
generating a test pattern using the test sequence generated;
performing a logic simulation on the circuit using the test pattern generated;
obtaining information that includes the test sequence with which the test pattern is generated, the first fault-detection information with which the test sequence is generated, and the fist terminal information of the terminal in which a fault is detected, when a result of the logic simulation includes an error; and
analyzing the error included in the result using the information obtained.
